(19) United States
(12) Patent Application Publication
(10) Pub. No.: US 2025/0359437 A1
(43) Pub. Date: Nov. 20, 2025

(54) DISPLAY DEVICE, ELECTRONIC DEVICE, AND MANUFACTURING METHOD OF DISPLAY DEVICE

(71) Applicant: Samsung Display Co., Ltd., Yongin-si (KR)

(72) Inventors: JOONYONG PARK, Yongin-si (KR); HYUNEOK SHIN, Yongin-si (KR); SUKYOUNG YANG, Yongin-si (KR); DONGMIN LEE, Yongin-si (KR); YU-GWANG JEONG, Yongin-si (KR)

(21) Appl. No.: 19/054,486

(22) Filed: Feb. 14, 2025

(30) Foreign Application Priority Data
May 14, 2024 (KR) 10-2024-0063063

(51) Int. Cl. H10K 59/122; H10K 59/12; H10K 71/60; H10K 102/00

(52) U.S. Cl. CPC H10K 59/122; H10K 59/1201; H10K 71/60; H10K 2102/351

(57) ABSTRACT

A display device includes a base layer, a lower electrode on the base layer, a sacrificial pattern which is on the lower electrode, and in which a lower opening exposing a portion of a top surface of the lower electrode is defined. An insulation film is on the base layer and covers at least a portion of the sacrificial pattern, and has a light-emitting opening corresponding to the lower opening. A conductive partition wall is on the insulation film, and has an upper opening corresponding to the light-emitting opening. In the sacrificial pattern, an atomic percent of indium may be less than about 0.1 at %.

### CROSS-REFERENCE TO RELATED APPLICATION

This application claims priority to and the benefit of Korean Patent Application No. 10-2024-0063063, filed on May 14, 2024, in the Korean Intellectual Property Office, the entire disclosure of which is incorporated herein by reference.

### BACKGROUND

### 1. Field

One or more aspects of embodiments of the present disclosure relate to a display device and a manufacturing method thereof. For example, the display device may include a sacrificial pattern.

### 2. Description of the Related Art

Multimedia electronic apparatuses, such as televisions, mobile phones, tablet PCs, computers, navigation systems, game consoles, and/or the like include a display panel to display an image.

A display panel includes a light-emitting element and a pixel circuit to drive the light-emitting element. Light-emitting elements, which are included in the display panel, emit light and generate an image in response to a voltage applied from the pixel circuit.

Research on a method of patterning a light-emitting element is in progress so as to improve reliability of a display panel, and recently, research is being conducted on a method of patterning, in units of a pixel, a light-emitting material that is provided in common by using an open mask.

### SUMMARY

One or more aspects of embodiments of the present disclosure are directed toward a display device with improved reliability.

One or more aspects of embodiments of the present disclosure are directed toward a manufacturing method of a display device with a simplified process.

However, it should be noted that these objectives are merely examples, and the scope of the disclosure is not limited to the herein-mentioned aspects. Rather, other objectives of one or more embodiments of the present disclosure will be apparent to those skilled in the art from the following descriptions.

Additional aspects of one or more embodiments will be set forth in part in the description which follows and, in part, will be apparent from the description, or may be learned by practice of the presented embodiments.

According to one or more embodiments, a display device includes a base layer; a lower electrode on the base layer; a sacrificial pattern which is on the lower electrode, and in which a lower opening exposing a portion of a top surface of the lower electrode is defined; an insulation film which is on the base layer and covers at least a portion of the sacrificial pattern, and in which a light-emitting opening corresponding to the lower opening is defined; and a conductive partition wall which is on the insulation film, and (e.g., including) in which an upper opening corresponding to the light-emitting opening is defined, wherein in the sacrificial pattern, an atomic percent (at %) of indium is less than about 0.1 at %.

In one or more embodiments, the sacrificial pattern may be doped with aluminum.

In one or more embodiments, in the sacrificial pattern, an atomic percent of the aluminum may be about 1 at % to about 5 at %.

In one or more embodiments, the sacrificial pattern may include at least one among selected from gallium oxide, zinc oxide, and tin oxide.

In one or more embodiments, the sacrificial pattern may include gallium zinc oxide or zinc tin oxide.

In one or more embodiments, a thickness of the sacrificial pattern may be about 100 angstroms (Å) to about 300 angstroms (Å).

In one or more embodiments, the sacrificial pattern may exclude (e.g., not include) indium.

In one or more embodiments, the display device may further include a light-emitting pattern that is inside the lower opening, the light-emitting opening, and the upper opening, and that is on the lower electrode; and an upper electrode that is on the light-emitting pattern, and that is on (e.g., contacting) an inner surface of the conductive partition wall, and the inner surface includes or defines the upper opening.

In one or more embodiments, the display device may further include a lower inorganic encapsulation film on the upper electrode and the conductive partition wall; an organic encapsulation film on the lower inorganic encapsulation film; and an upper inorganic encapsulation film on the organic encapsulation film, and the lower inorganic encapsulation film may be on (e.g., in contact with) an inner surface of the conductive partition wall, which defines the upper opening.

In one or more embodiments, the display device may further include a capping pattern between the upper electrode and the lower inorganic encapsulation film.

In one or more embodiments, the conductive partition wall may include a first conductive layer having a first conductivity, and a second conductive layer on the first conductive layer and having a second conductivity less (lower) than the first conductivity, and a thickness of the first conductive layer may be greater than a thickness of the second conductive layer.

In one or more embodiments, an inner surface of the first conductive layer may have or define a first region of the upper opening, an inner surface of the second conductive layer may have or define a second region of the upper opening, and based on a cross-section of the display device, the inner surface of the second conductive layer, which defines the second region, may be closer (more adjacent) to a center of the lower electrode than to the inner surface of the first conductive layer, which defines the first region.

In one or more embodiments, a distance between the inner surface of the first conductive layer and the inner surface of the second conductive layer in the first region is substantially equal to a distance between the inner surface of the first conductive layer and the inner surface of the second conductive layer in the second region. In embodiments, a distance between the inner surface of the first conductive layer and the inner surface of the second conductive layer may be substantially the same throughout all regions.

In one or more embodiments of the present disclosure, an electronic device includes a display module, a window on the display module, and a housing under the display module, wherein the display module includes a base layer; a lower electrode on the base layer; a sacrificial pattern which is on the lower electrode, and in which a lower opening exposing a portion of a top surface of the lower electrode is defined; an insulation film which is on the base layer and covers at least a portion of the sacrificial pattern, and in which a light-emitting opening corresponding to the lower opening is defined; and a conductive partition wall which is on the insulation film, and in which an upper opening corresponding to the light-emitting opening is defined, wherein the sacrificial pattern excludes (e.g., does not include) indium.

In one or more embodiments of the present disclosure, a manufacturing method of a display device includes providing a preliminary display panel including a base layer, a lower electrode on the base layer, a sacrificial pattern on the lower electrode, and an insulation film on the base layer and covering the lower electrode and the sacrificial pattern; providing (forming) a light-emitting opening in the insulation film; providing (forming) a conductive partition wall layer on the insulation film, and that includes the light-emitting opening (e.g., in which the light-emitting opening is provided (formed)); providing (forming), in the conductive partition wall layer, an upper opening corresponding to the light-emitting opening; and providing (forming) a lower opening in the sacrificial pattern.

In one or more embodiments, the manufacturing method may further include providing (forming) a light-emitting pattern on the lower electrode, and the light-emitting pattern is inside the upper opening, the light-emitting opening, and the lower opening; and providing (forming) an upper electrode on the light-emitting pattern and the upper electrode is on (e.g., in contact with) an inner surface of a first conductive layer having (which defines) the upper opening.

In one or more embodiments, in the sacrificial pattern, an atomic percent of indium may be less than about 0.1 at %.

In one or more embodiments, the conductive partition wall layer may include a first conductive layer and a second conductive layer on the first conductive layer, and the providing (forming) of the upper opening may include providing (forming) a preliminary upper opening in the conductive partition wall layer by dry-etching the first conductive layer and the second conductive layer, and providing (forming) the upper opening from the preliminary upper opening by wet-etching the first conductive layer and the second conductive layer to provide (so that) a conductive partition wall from the conductive partition wall layer, and a chlorine-containing etching gas may be used during the dry-etching.

In one or more embodiments, the providing (forming) of the lower opening in the sacrificial pattern may be performed by using wet etching, and an etch rate of the lower electrode may be less (smaller) than an etch rate of the sacrificial pattern.

In one or more embodiments, the sacrificial pattern may be doped with aluminum, and may include at least one selected from among gallium oxide, zinc oxide, and tin oxide.

### BRIEF DESCRIPTION OF THE DRAWINGS

The accompanying drawings are included to provide a further understanding of the preceding and other aspects and features of one or more embodiments of the present disclosure, and are incorporated in and constitute a part of this specification. The drawings illustrate example embodiments that will be more apparent from the following description taken in conjunction with the accompanying drawings and, together with the description, serve to explain principles of the present disclosure. In the drawings:

FIG. 1A is a perspective view of a display device according to one or more embodiments of the present disclosure;

FIG. 1B is an exploded perspective view of a display device according to one or more embodiments of the present disclosure;

FIG. 2 is a cross-sectional view of a display panel according to one or more embodiments of the present disclosure;

FIG. 3 is a plan view of a display panel according to one or more embodiments of the present disclosure;

FIG. 4 is an enlarged plan view of a portion of a display region of a display panel according to one or more embodiments of the present disclosure;

FIG. 5A is a cross-sectional view of a display panel according to one or more embodiments of the present disclosure taken along line I-I′ of FIG. 4;

FIG. 5B is a cross-sectional view of a display panel according to one or more embodiments of the present disclosure taken along line II-II′ of FIG. 4;

FIG. 6 is an enlarged cross-sectional view of a portion of a display panel according to one or more embodiments of the present disclosure; and

FIGS. 7A-7L are cross-sectional views each illustrating steps of a manufacturing method of a display device according to one or more embodiments of the present disclosure.

### DETAILED DESCRIPTION

Reference will now be made in more detail to embodiments, and the present disclosure has embodiments that may have different forms and should not be construed as being limited to the descriptions set forth herein. Rather, these embodiments are provided so that this disclosure will be thorough and complete, and will fully convey the scope of the present disclosure to those skilled in the art. Accordingly, the embodiments are merely described herein, by referring to the figures, to explain aspects of example embodiments of the present description.

In this specification, it will be understood that when an element (or region, layer, portion, and/or the like) is referred to as being “on”, “connected to” or “coupled to” another element or layer, it can be directly on/connected to/coupled to the other element or intervening elements may be present.

Hereinafter, one or more embodiments will be described in detail with reference to the accompanying drawings, wherein like reference numerals or symbols refer to like elements throughout the specification. As the disclosure allows for one or more suitable changes and numerous embodiments, certain embodiments will be illustrated in the drawings and described in the detailed description. Effects and features of the disclosure, and methods for achieving them will be clarified with reference to embodiments described herein in more detail with reference to the drawings. However, the subject matter of the disclosure is not limited to the following embodiments and may be embodied in one or more suitable forms. In some embodiments, in terms of drawings, the thickness and the ratio and the dimension of the element may be exaggerated for effective description of the technical contents. As used herein, the term “and/or” includes any and all combinations of one or more of the associated listed items.

Throughout the disclosure, the expression “at least one of a, b or c” indicates: only a, only b, only c; both (e.g., simultaneously) a and b; both (e.g., simultaneously) a and c; both (e.g., simultaneously) b and c; all of a, b, and c; or variations thereof. As used herein, “A and/or B” may select only A, select only B, or select both (e.g., simultaneously) A and B. “At least one of A or B” is used herein to select only A, select only B, or select both (e.g., simultaneously) A and B.

Terms such as “first” and “second” may be used to describe various components, but the components should not be limited by the terms. These terms are only used for the purpose of distinguishing one component from other components. For example, without departing from the scope of the present disclosure, a first component may be referred to as a second component, and similarly, a second component may be referred to as a first component. Singular expressions such as “a,” “an,” and “the” include plural expressions unless the context clearly indicates otherwise.

Spatially relative terms, such as “beneath”, “below”, “lower”, “above”, “upper” and/or the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the drawings is turned over, elements described as “below” or “beneath” other elements or features would then be oriented “above” or “over” the other elements or features. Thus, the term “below” may encompass both an orientation (e.g., simultaneously) of above and below. The device may be otherwise oriented (rotated 90 degrees or at other orientations), and the spatially relative descriptors used herein should be interpreted accordingly.

It will be further understood that the terms “comprise,” “comprises,” “comprising,” “has,” “have,” “having,” “include,” “includes,” and/or “including”, when used in this specification, specify the presence of stated features, integers, steps, operations, elements, and/or components, but do not preclude the presence or addition of one or more other features, integers, steps, operations, elements, components, and/or groups thereof.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this context, “consisting essentially of” indicates that any additional components will not materially affect the chemical, physical, optical or electrical properties of the semiconductor film.

Further, in this specification, the phrase “plan view,” indicates viewing a target portion from the top, and the phrase “on a cross-section” indicates viewing a cross-section formed by vertically cutting a target portion from the side.

Hereinafter, embodiments of the present disclosure will be described with reference to the accompanying drawings.

### Display Device

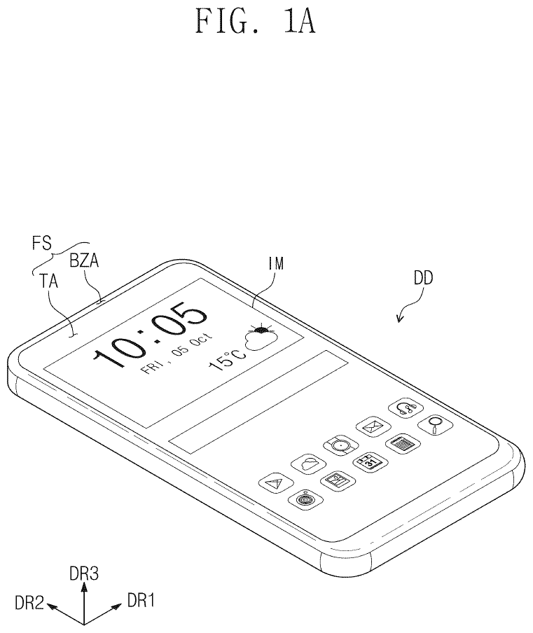

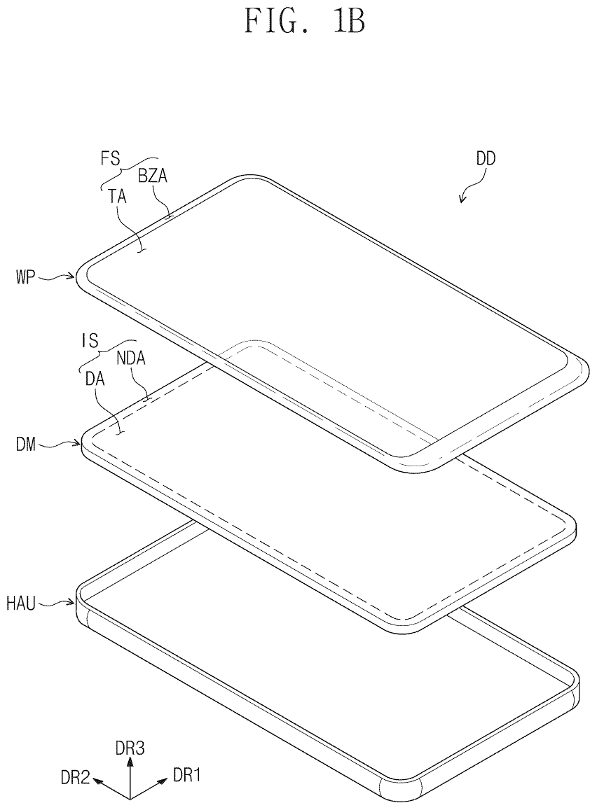

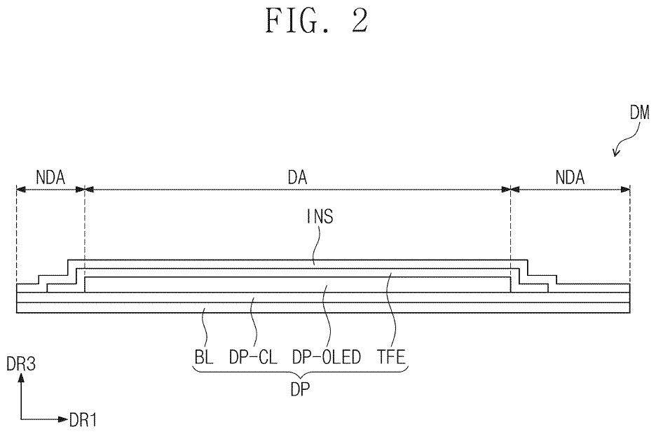

FIG. 1A is a perspective view of a display device according to one or more embodiments of the present disclosure. FIG. 1B is an exploded perspective view of a display device according to one or more embodiments of the present disclosure. FIG. 2 is a cross-sectional view of a display panel according to one or more embodiments of the present disclosure.

In one or more embodiments, a display device DD may be a large-sized electronic device such as a television, a monitor, or an outdoor billboard. In some embodiments, the display device DD may be a small- and medium-sized electronic device such as a personal computer, a notebook computer, a personal digital assistant, a car navigation unit, a game console, a smartphone, a tablet PC, and/or a camera. Such devices are presented as examples only, and other display devices may also be employed unless deviating from the spirit and scope of the present disclosure. In this embodiment, the display device as an example DD is illustrated as a smartphone.

Referring to FIGS. 1A, 1B, and 2, the display device DD may display an image IM, toward a third direction DR3, on a display surface FS that is parallel to each of a first direction DR1 and a second direction DR2. The image IM may include a static image as well as (and/or) a dynamic image. In FIG. 1, a clock window and icons are illustrated as one example of the image IM. The display surface FS on which the image IM is displayed may correspond to a front surface of the display device DD.

In one or more embodiments, a front surface (or top surface) and a rear surface (or lower surface) of each member are defined on the basis of a direction in which the image IM is displayed. The front surface and the rear surface may be opposed to each other in the third direction DR3, and the normal direction of each of the front surface and the rear surface may be parallel to the third direction DR3. The directions indicated by the first to third directions DR1, DR2, and DR3 may have a relative relationship and may thus be changed to other directions. In this specification, the wording “on a plane” may refer to “when viewed in the third direction DR3”.

As illustrated in FIG. 1B, the display device DD according to one or more embodiments may include a window WP, a display module DM, and a housing HAU. The window WP and the housing HAU may be coupled to each other to include (e.g., constitute) an exterior of the display device DD.

The window WP may include an optically transparent insulation material. For example, the window WP may include glass and/or plastic. A front surface of the window WP may define the display surface FS of the display device DD. The display surface FS may include a transmission region TA and a bezel region BZA. The transmission region TA may be an optically transparent region. For example, the transmission region TA may be a region having a visible light transmittance of about 90% or more.

The bezel region BZA may be a region having a relatively lower (less) light transmittance than the transmission region TA. The bezel region BZA may define the shape of the transmission region TA. The bezel region BZA may be adjacent to the transmission region TA, and may surround the transmission region TA. This is illustrated, as an example, and the bezel region BZA may not be provided in the window WP according to one or more embodiments of the present disclosure. The window WP may include at least any one functional layer among an anti-fingerprint layer, a hard coating layer, and an anti-reflection layer, and the present disclosure is not limited to any one embodiment.

The display module DM may be below or under the window WP. The display module DM may be a component which substantially generates the image IM. The image IM generated from display module DM may be displayed on a display surface IS of the display module DM, and may be viewed by a user from the outside, through the transmission region TA.

The display module DM may include a display region DA and a non-display region NDA. The display region DA may be activated in response to an electrical signal. The non-display region NDA may be adjacent to the display region DA. The non-display region NDA may surround the display region DA. The non-display region NDA may be a region covered by the bezel region BZA, and may be unobserved (invisible) from the outside.

As illustrated in FIG. 2, the display module DM according to one or more embodiments may include a display panel DP and an input sensor INS. The display device DD according to one or more embodiments of the present disclosure may further include a protective member on a bottom surface of the display panel DP, or an anti-reflective member and/or a window member on a top surface of the input sensor INS.

The display panel DP may be a light-emitting display panel, and is not particularly limited. For example, the display panel DP may be an organic light-emitting display panel or an inorganic light-emitting display panel. A light-emitting layer inside the organic light-emitting display panel may include an organic light-emitting material. A light-emitting layer inside the inorganic light-emitting display panel may include quantum dots, quantum rods, and/or micro-LEDs. Hereinafter, the display panel DP will be described in more detail as the organic light-emitting display panel.

The display panel DP may include a base layer BL, a circuit element layer DP-CL on the base layer BL, a display element layer DP-OLED, and a thin-film encapsulation layer TFE. The input sensor INS may be directly on the thin-film encapsulation layer TFE. In this specification, the wording “a component A may be directly on a component B” refers to that an adhesive layer is not between the component A and the component B.

The base layer BL may include at least one plastic film. The base layer BL may be a flexible substrate, and may include a plastic substrate, a glass substrate, a metal substrate, an organic/inorganic composite material substate, and/or the like. The display region DA and the non-display region NDA which have been described with reference to FIG. 1B may be similarly defined on the base layer BL.

The circuit element layer DP-CL includes at least one insulation layer and a circuit element. The insulation layer includes at least one inorganic layer and at least one organic layer. The circuit element includes signal lines, a drive circuit of a pixel, and/or the like.

The display element layer DP-OLED includes a conductive partition wall and a light-emitting element. The light-emitting element includes a lower electrode, a light-emitting pattern and an upper electrode.

The thin-film encapsulation layer TFE includes a plurality of thin films. Some of the thin films may enhance or improve optical efficiency, and some of the thin films may enhance or protect organic light-emitting diodes.

The input sensor INS obtains coordinate information about an external input. The input sensor INS may have a multi-layered structure. The input sensor INS may include a single- or multi-layered conductive layer. The input sensor INS may include a single- or multi-layered insulation layer. The input sensor INS may sense an external input, for example, in a capacitive manner. An operating method of the input sensor INS according to embodiments of the present disclosure is not particularly limited, and in one or more embodiments of the present disclosure, the input sensor INS may sense an external input in an electromagnetic induction manner or in a pressure sensitive manner. In another embodiment of the present disclosure, the input sensor INS may not be provided.

Referring to what is illustrated in FIG. 1B again, the housing HAU and the window WP may be coupled to each other. The housing HAU may be coupled to the window WP to provide an inner space. The display module DM may be accommodated in the inner space.

The housing HAU may include a material with relatively high rigidity. For example, the housing HAU may include a plurality of frames and/or plates including glass, plastic, or metal, or including (e.g., composed of) a combination thereof. The housing HAU may stably protect components of the display device DD, which are accommodated in the inner space, from external impacts.

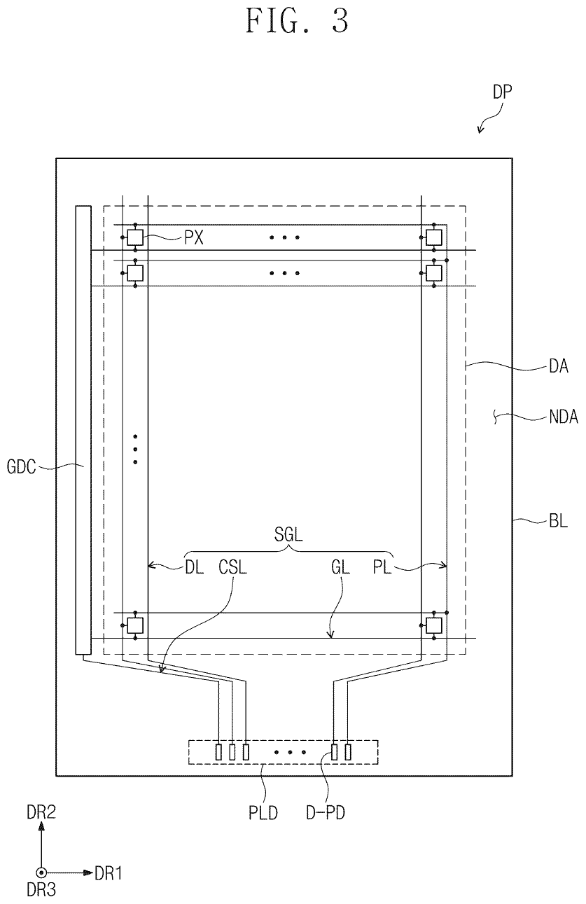

FIG. 3 is a plan view of a display panel according to one or more embodiments of the present disclosure.

Referring to FIG. 3, a display panel DP may include a base layer BL divided into the display region DA and the non-display region NDA which have been described with reference to FIG. 2.

The display panel DP may include pixels PX and signal lines SGL which are in the display region DA, and the signal lines SGL are electrically coupled or connected to the pixels PX. The display panel DP may include a drive circuit GDC and a pad part PLD which are in the non-display region NDA.

The pixels PX may be arranged in a first direction DR1 and a second direction DR2. The pixels PX may include a plurality of pixel rows extending in the first direction DR1 and arranged in the second direction DR2, and a plurality of pixel columns extending in the second direction DR2 and arranged in the first direction DR1.

The signal lines SGL may include gate lines GL, data lines DL, a power supply line PL, and a control signal line CSL. The gate lines GL may each be coupled or connected to a corresponding pixel among the pixels PX, and the data lines DL may each be coupled or connected to a corresponding pixel among the pixels PX. The power supply line PL may be electrically coupled or connected to the pixels PX. The control signal line CSL may be coupled or connected to the drive circuit GDC to provide control signals to the drive circuit GDC.

The drive circuit GDC may include a gate drive circuit. The gate drive circuit may generate gate signals, and sequentially output the generated gate signals to the gate lines GL. The gate drive circuit may further output another control signal to a pixel drive circuit.

The pad part PLD may be a part to which a flexible printed circuit board is connected. The pad part PLD may include pixel pads D-PD, and the pixel pads D-PD may be pads to connect the flexible printed circuit board to the display panel DP. The pixel pads D-PD may each be coupled or connected to a corresponding signal line among the signal lines SGL. The pixel pads D-PD may be respectively coupled or connected to the corresponding pixels PX through the signal lines SGL. In some embodiments, one pixel pad among the pixel pads D-PD may be coupled or connected to the drive circuit GDC.

In some embodiments, the pad part PLD may further include input pads. The input pads may be pads to couple or connect the flexible printed circuit board to the input sensor INS (see FIG. 2). However, one or more embodiments of the present disclosure is not limited thereto, and the input pads may be on the input sensor INS (see FIG. 2) and coupled or connected to a circuit board separate from the pixel pads D-PD. In embodiments, the input sensor INS (see FIG. 2) may not be provided, and may not further include the input pads.

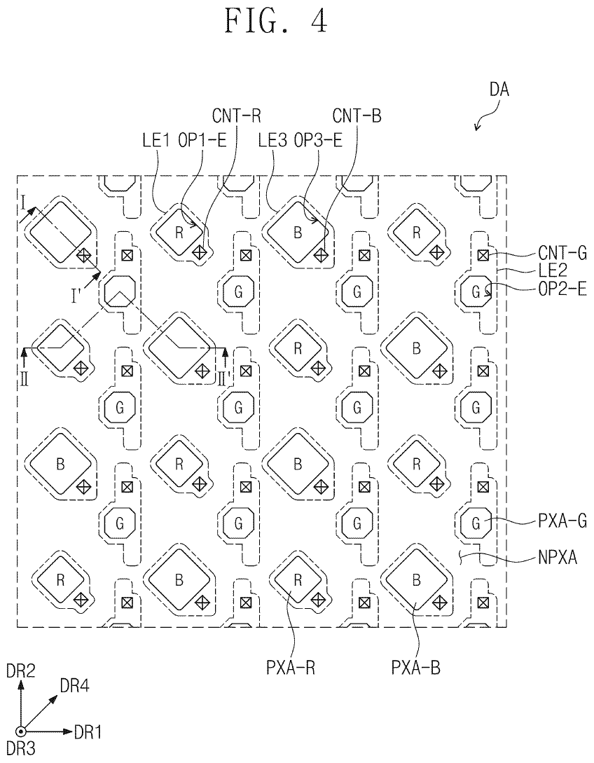

FIG. 4 is an enlarged plan view of a portion of a display region of a display panel according to one or more embodiments of the present disclosure. FIG. 4 illustrates a plan view of the display module DM (see FIG. 2) when viewed from above the display surface IS (see FIG. 2) of the display module DM (see FIG. 2), and illustrates an arrangement of light-emitting regions PXA-R, PXA-G, and PXA-B.

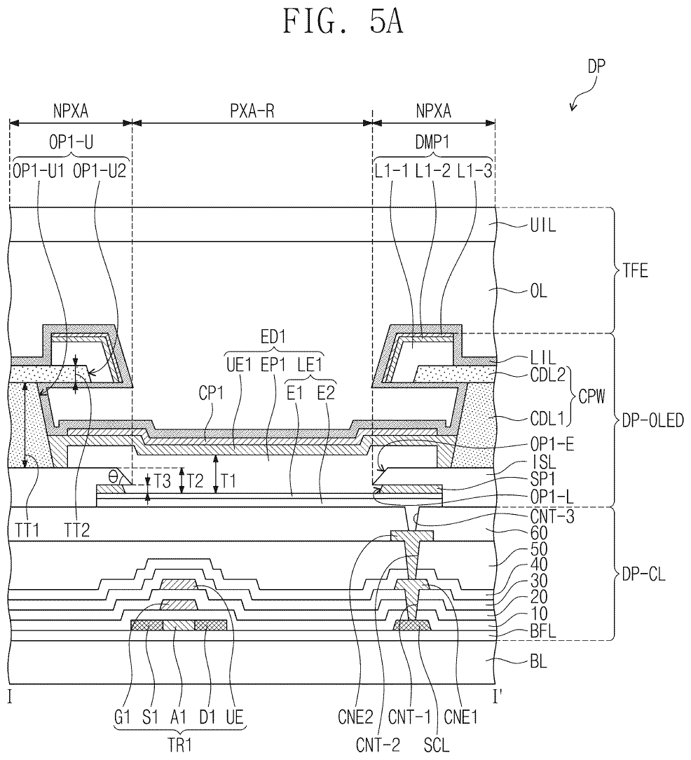

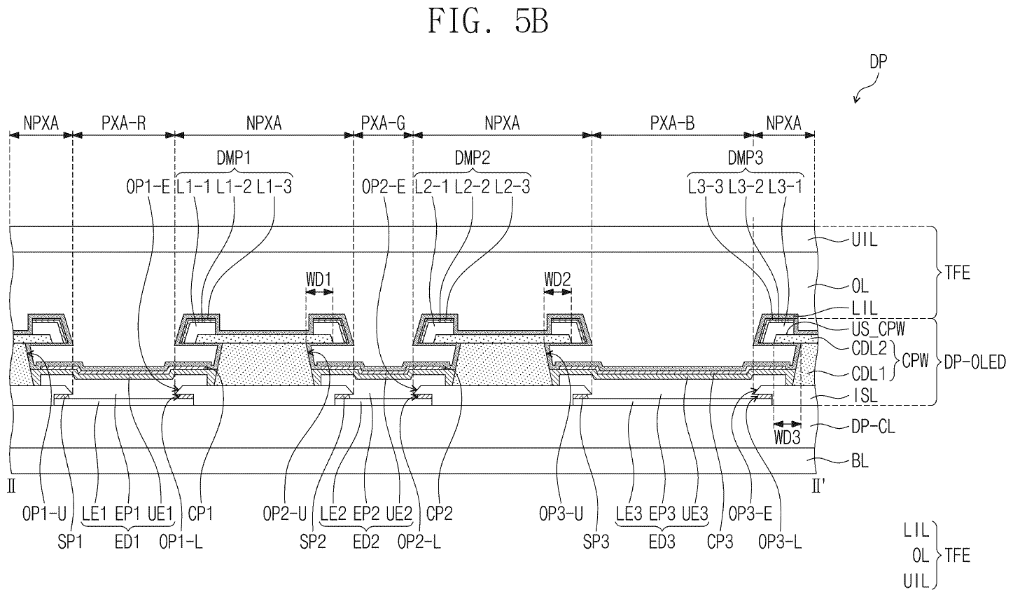

Referring to FIG. 4, a display region DA may include first to third light-emitting regions PXA-R, PXA-G, and PXA-B, and a non-light emitting region NPXA around (surrounding) the first to third light-emitting regions PXA-R, PXA-G, and PXA-B. The first to third light-emitting regions PXA-R, PXA-G, and PXA-B may respectively correspond to regions where light provided from first to third light-emitting elements ED1, ED2, and ED3 (see FIG. 5B) is emitted. FIG. 4 illustrates, for example, lower electrodes LE1, LE2, and LE3 only among the components of the light-emitting elements ED1, ED2, and ED3 (see FIG. 5B) for convenience of explanation. The first to third light-emitting regions PXA-R, PXA-G, and PXA-B may be distinguished depending on a color of light emitted toward the outside.

The first to third light-emitting regions PXA-R, PXA-G, and PXA-B may respectively provide first- to third-color light having colors different from each other. For example, the first-color light may be red light, the second-color light may be green light, and the third-color light may be blue light. However, an example of the first- to third-color light is not necessarily limited to the preceding example.

The first to third light-emitting regions PXA-R, PXA-G, and PXA-B may be respectively included (defined) as regions, of top surfaces of the corresponding lower electrodes LE1, LE2, and LE3, exposed by corresponding light-emitting openings OP1-E, OP2-E, and OP3-E. In one or more embodiments, the light-emitting openings OP1-E, OP2-E, and OP3-E may be provided (defined) in an insulation film ISL (see FIG. 5B) covering portions of the lower electrodes LE1, LE2, and LE3, and a detailed explanation thereof will be provided in more detail.

The first light-emitting region PXA-R may be provided (defined) as a region, of a top surface of the first lower electrode LE1, exposed by the first light-emitting opening OP1-E, the second light-emitting region PXA-G may be provided (defined) as a region, of a top surface of the second lower electrode LE2, exposed by the second light-emitting opening OP2-E, and the third light-emitting region PXA-B may be provided (defined) as a region, of a top surface of the third lower electrode LE3, exposed by the third light-emitting opening OP3-E.

The non-light emitting region NPXA may provide (demarcate) boundaries of the first to third light-emitting regions PXA-R, PXA-G, and PXA-B, and may prevent or reduce color mixing between the first to third light-emitting regions PXA-R, PXA-G, and PXA-B.

The first to third light-emitting regions PXA-R, PXA-G, and PXA-B may each be provided in plurality, and may be repeatedly arranged while having an arrangement form within the display region DA. For example, the first and third light-emitting regions PXA-R and PXA-B may be alternately arranged along a first direction DR1 to provide (constitute) a ‘first group’. The second light-emitting regions PXA-G may be arranged along the first direction DR1 to provide (constitute) a ‘second group’. The ‘first group’ and the ‘second group’ may each be provided in plurality, and the ‘first groups’ and the second groups' may be alternately arranged along a second direction DR2.

One second light-emitting region PXA-G may be spaced and/or apart (e.g., spaced apart or separated) from one first light-emitting region PXA-R or one third light-emitting region PXA-B in a fourth direction DR4. The fourth direction DR4 may be defined as a direction between the first and second directions DR1 and DR2.

FIG. 4 illustrates an example of an arrangement form of the first to third light-emitting regions PXA-R, PXA-G, and PXA-B. One or more embodiments of the present disclosure is not limited thereto, and the first to third light-emitting regions may be arranged in one or more suitable forms. In one or more embodiments, as illustrated in FIG. 4, the first to third light-emitting regions PXA-R, PXA-G, and PXA-B may have a pentile (PENTILE®) arrangement form or structure (e.g., an RGBG matrix, an RGBG structure, or an RGBG matrix structure). In embodiments, the first to third light-emitting regions PXA-R, PXA-G, and PXA-B may have a stripe arrangement form, or a diamond (DIAMOND PIXEL™) arrangement form or structure, (e.g., a display (e.g., an OLED display) containing red, blue, and green (RGB) light emitting regions arranged in the shape of diamonds). PENTILE® and DIAMOND PIXEL™ are trademarks owned by Samsung Display Co., Ltd.

The first to third light-emitting regions PXA-R, PXA-G, and PXA-B may have one or more suitable shapes on a plane. For example, the first to third light-emitting regions PXA-R, PXA-G, and PXA-B may have shapes such as polygonal shapes, circular shapes, and/or oval shapes. FIG. 4, for example, illustrates that on a plane, the first and third light-emitting regions PXA-R and PXA-B have a quadrangular shape (or rhombus shape), and the second light-emitting region PXA-G has an octagonal shape.

The first to third light-emitting regions PXA-R, PXA-G, and PXA-B may have substantially the same shape on a plane, or at least some regions may have different shapes. FIG. 4 exemplarily illustrates that on a plane, the first and third light-emitting regions PXA-R and PXA-B have substantially the same shape, and the second light-emitting region PXA-G has a different shape from the first and third light-emitting regions PXA-R and PXA-B.

At least some of the first to third light-emitting regions PXA-R, PXA-G, and PXA-B may have different areas on a plane. In one or more embodiments, an area of the first light-emitting region PXA-R, which emits red light, may be greater than an area of the second light-emitting region PXA-G, which emits green light, and may be smaller than an area of the third light-emitting region PXA-B, which emits blue light. However, a size relationship of the areas between the first to third light-emitting regions PXA-R, PXA-G, and PXA-B according to the color of emitted light is not limited thereto, and may vary depending on a design of the display module DM (see FIG. 2). In embodiments, one or more embodiments of the present disclosure is not limited thereto, and the first to third light-emitting regions PXA-R, PXA-G, and PXA-B may have substantially the same area on a plane.

The shapes, areas, arrangements, and/or the like of the first to third light-emitting regions PXA-R, PXA-G, and PXA-B of the display module DM (see FIG. 2) according to embodiments of the present disclosure may be suitably designed in accordance with a color of emitted light, or a size and configuration of the display module DM (see FIG. 2), and the present disclosure is not limited to the embodiment illustrated in FIG. 4.

The lower electrodes LE1, LE2, and LE3 may be coupled or connected to drive circuits of a pixel inside the aforementioned circuit element layer DP-CL (see FIG. 2) through connection contact holes CNT-R, CNT-G, and CNT-B. The connection contact holes CNT-R, CNT-G, and CNT-B may include a first connection contact hole CNT-R, a second connection contact hole CNT-G, and a third connection contact hole CNT-B. The first connection contact hole CNT-R may be provided (defined) as a region coupled or connected to the drive circuit of the pixel to which the first lower electrode LE1 corresponds, the second connection contact hole CNT-G may be provided (defined) as a region coupled or connected to the drive circuit of the pixel to which the second lower electrode LE2 corresponds, and the third connection contact hole CNT-B may be provided (defined) as a region coupled or connected to the drive circuit of the pixel to which the third lower electrode LE3 corresponds.

The connection contact holes CNT-R, CNT-G, and CNT-B may be respectively spaced and/or apart (e.g., spaced apart or separated) from the light-emitting regions PXA-R, PXA-G, and PXA-B which are provided (defined) in the lower electrodes LE1, LE2, and LE3. However, this is merely an example, and the connection contact holes CNT-R, CNT-G, and CNT-B may be respectively overlapping the light-emitting regions PXA-R, PXA-G, and PXA-B which are provided (defined) in the lower electrodes LE1, LE2, and LE3. The connection contact holes CNT-R, CNT-G, and CNT-B will be described in more detail herein.

FIG. 5A is a cross-sectional view of a display panel according to one or more embodiments of the present disclosure taken along line I-I′ of FIG. 4. FIG. 5B is a cross-sectional view of a display panel according to one or more embodiments of the present disclosure taken along line II-II′ of FIG. 4.

Referring to FIGS. 5A and 5B, a display panel DP may include a base layer BL, a circuit element layer DP-CL, a display element layer DP-OLED, and a thin-film encapsulation layer TFE.

The base layer BL may include a synthetic resin film. In some embodiments, the base layer BL may include a glass substrate, a metal substrate, an organic/inorganic composite material substrate, and/or the like.

At least one inorganic layer may be on a top surface of the base layer BL. A buffer layer BFL may enhance or improve a coupling force between the base layer BL and a semiconductor pattern. The buffer layer BFL may include a silicon oxide layer and/or a silicon nitride layer. The silicon oxide layer and/or the silicon nitride layer may be alternately stacked.

The display panel DP may include a plurality of insulation layers, a semiconductor pattern, a conductive pattern, a signal line, and/or the like. An insulation layer, a semiconductor layer, and a conductive layer are formed through coating, deposition and/or the like. Then, the insulation layer, the semiconductor layer, and the conductive layer may be selectively patterned through photolithography and etching. In this manner, the semiconductor pattern, the conductive pattern, the signal line, and/or the like, which are included in the circuit element layer DP-CL and the display element layer DP-OLED, are provided (formed).

The semiconductor pattern may be on the buffer layer BFL. The semiconductor pattern may include polysilicon. However, one or more embodiments of the present disclosure is not limited thereto, and the semiconductor pattern may include amorphous silicon and/or metal oxide.

FIG. 5A illustrates only a portion of the semiconductor pattern, and the semiconductor pattern may also be in a plurality of light-emitting regions PXA-R, PXA-G, and PXA-B. The semiconductor patterns may be arranged in accordance with a suitable pattern across the plurality of light-emitting regions PXA-R, PXA-G, and PXA-B. The semiconductor pattern may have different electrical properties depending on whether to be doped or not. The semiconductor pattern may include a first region with high doping concentration and a second region with low doping concentration. The first region may be doped with an N-type (kind) dopant or a P-type (kind) dopant. A P-type (kind) transistor may include the first region that is doped with the P-type (kind) dopant.

The first region may have higher conductivity than the second region, and substantially serves as an electrode or a signal line. The second region may substantially correspond to an active (or channel) of a transistor. For example, a portion of the semiconductor pattern may be the active of the transistor, another portion may be a source or drain of the transistor, and still another portion may be a conductive region.

As illustrated in FIG. 5A, a source S1, an active A1, and a drain D1 of a transistor TR1 may be provide (formed) from the semiconductor pattern. FIG. 5A illustrates a portion of a signal transmission region SCL provide (formed) from the semiconductor pattern. In one or more embodiments, the signal transmission region SCL may be coupled or connected to the drain D1 of the transistor TR1 on a plane.

First to sixth insulation layers 10 to 60 may be on the buffer layer BFL. The first to sixth insulation layers 10 to 60 may be inorganic layers and/or organic layers. A gate G1 may be on the first insulation layer 10. An upper electrode UE may be on the second insulation layer 20. A first connection electrode CNE1 may be on the third insulation layer 30. The first connection electrode CNE1 may be coupled or connected to the signal transmission region SCL via a contact hole CNT-1 which passes through the first to third insulation layers 10 to 30. The fourth insulation layer 40 may be on the third insulation layer 30, and may cover the first connection electrode CNE1. The fifth and sixth insulation layers 50 and 60 may be on the fourth insulation layer 40. In one or more embodiments, the fifth and sixth insulation layers 50 and 60 may be organic layers.

A second connection electrode CNE2 may be on the fifth insulation layer 50. The second connection electrode CNE2 may be coupled or connected to the first connection electrode CNE1 via a contact hole CNT-2 which passes through the fourth and fifth insulation layers 40 and 50.

The display element layer DP-OLED may be on the circuit element layer DP-CL. According to this embodiment, the display element layer DP-OLED may include light-emitting elements ED1, ED2, and ED3, sacrificial patterns SP1, SP2, and SP3, an insulation film ISL, a conductive partition wall CPW, dummy patterns DMP1, DMP2, and DMP3, and a dummy inorganic layer LIL2-D.

The light-emitting elements ED1, ED2, and ED3 may include a first light-emitting element ED1, a second light-emitting element ED2, and a third light-emitting element ED3. The first light-emitting element ED1 may include a first lower electrode LE1, a first light-emitting pattern EP1, and a first upper electrode UE1, the second light-emitting element ED2 may include a second lower electrode LE2, a second light-emitting pattern EP2, and a second upper electrode UE2, and the third light-emitting element ED3 may include a third lower electrode LE3, a third light-emitting pattern EP3, and a third upper electrode UE3.

The first to third lower electrodes LE1, LE2, and LE3 may each be provided as a plurality of patterns. Hereinafter, a description will be provided focusing on the first lower electrode LE1, and the description of the first lower electrode LE1 will be similarly applied to the second and third lower electrodes LE2 and LE3.

The first lower electrode LE1 may be on the sixth insulation layer 60 of the circuit element layer DP-CL. The first lower electrode LE1 may be coupled or connected to the second connection electrode CNE2 via a connection contact hole CNT-3 which is provided or defined by passing through the sixth insulation layer 60. Accordingly, the first lower electrode LE1 may be electrically coupled or connected to the signal transmission region SCL via the first and second connection electrodes CNE1 and CNE2, and thus electrically coupled or connected to a corresponding circuit element. The connection contact hole CNT-3 in FIG. 5A may correspond to the first connection contact hole CNT-R in FIG. 4.

The first lower electrode LE1 may be a (semi-) transmissive electrode or a reflective electrode. In this embodiment, the first lower electrode LE1 may include a first layer E1 and a second layer E2.

The first layer E1 may include a metal material. For example, the first layer E1 may be a reflective layer formed of silver (Ag), magnesium (Mg), aluminum (Al), platinum (Pt), palladium (Pd), gold (Au), nickel (Ni), neodymium (Nd), iridium (Ir), chromium (Cr), a compound thereof, and/or the like.

The second layer E2 may be on the first layer E1. The second layer E2 may include a transparent conductive oxide. For example, the second layer E2 may be a transparent or translucent electrode layer including at least one selected from among groups including (e.g., containing) indium tin oxide (ITO), indium zinc oxide (IZO), indium gallium zinc oxide (IGZO), zinc oxide (ZnO) or indium oxide (In₂O₃), and aluminum-doped zinc oxide (AZO). In this embodiment, the second layer E2 may include a crystallized transparent conductive oxide, and for example, the transparent conductive oxide may include poly-ITO.

In one or more embodiments, the first lower electrode LE1 may further include a third layer under the first layer E1. The third layer may include a transparent conductive oxide. In embodiments, the third layer and the second layer E2 may include the same material or may include different materials.

The sacrificial patterns SP1, SP2, and SP3 may include a first sacrificial pattern SP1 on a top surface of the first lower electrode LE1, a second sacrificial pattern SP2 on a top surface of the second lower electrode LE2, and a third sacrificial pattern SP3 on a top surface of the third lower electrode LE3.

A first lower opening OP1-L exposing a portion of the top surface of the first lower electrode LE1 may be provided or defined in the first sacrificial pattern SP1, a second lower opening OP2-L exposing a portion of the top surface of the second lower electrode LE2 may be provided or defined in the second sacrificial pattern SP2, and a third lower opening OP3-L exposing a portion of the top surface of the third lower electrode LE3 may be provided or defined in the third sacrificial pattern SP3.

According to embodiments of the present disclosure, during an etching process of the first sacrificial pattern SP1 for forming the first lower opening OP1-L, the first lower electrode LE1 may be prevented from being etched together and damaged, and the description thereof may be similarly applied to the second sacrificial pattern SP2 and the third sacrificial pattern SP3.

In each of the first to third sacrificial patterns SP1, SP2, and SP3, an atomic percent (at %) of indium may be less than about 0.1 at %. Each of the first to third sacrificial patterns SP1, SP2, and SP3 may not include indium. The first to third sacrificial patterns SP1, SP2, and SP3 may not include indium, thereby preventing a reaction byproduct from contaminating a chamber during a dry etching process to form the conductive partition wall CPW.

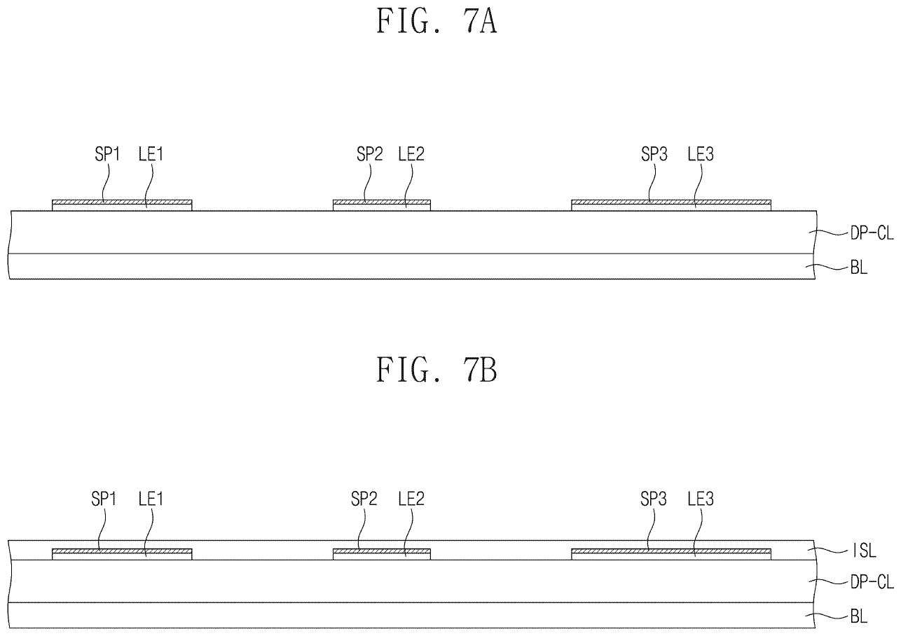

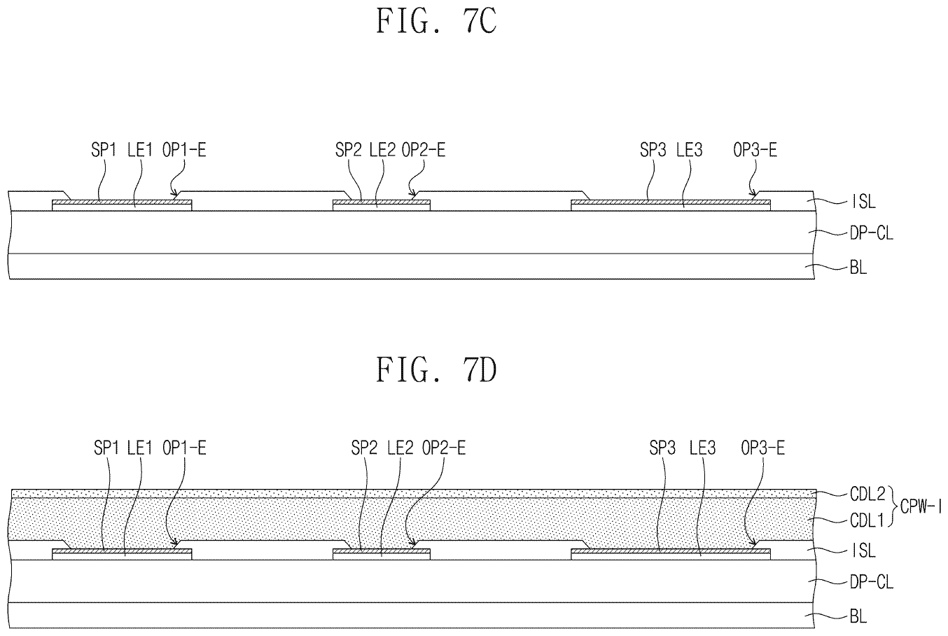

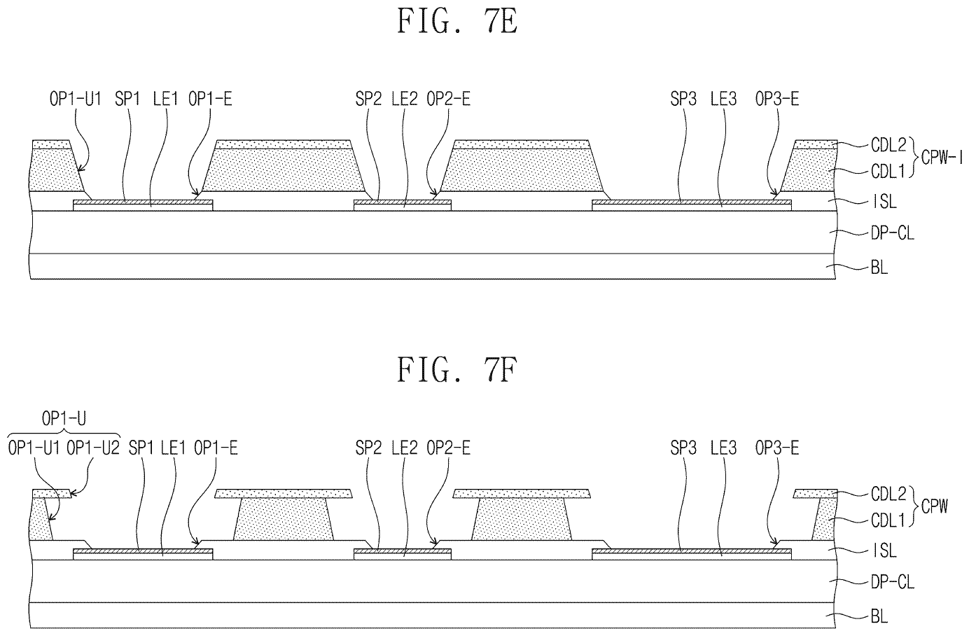

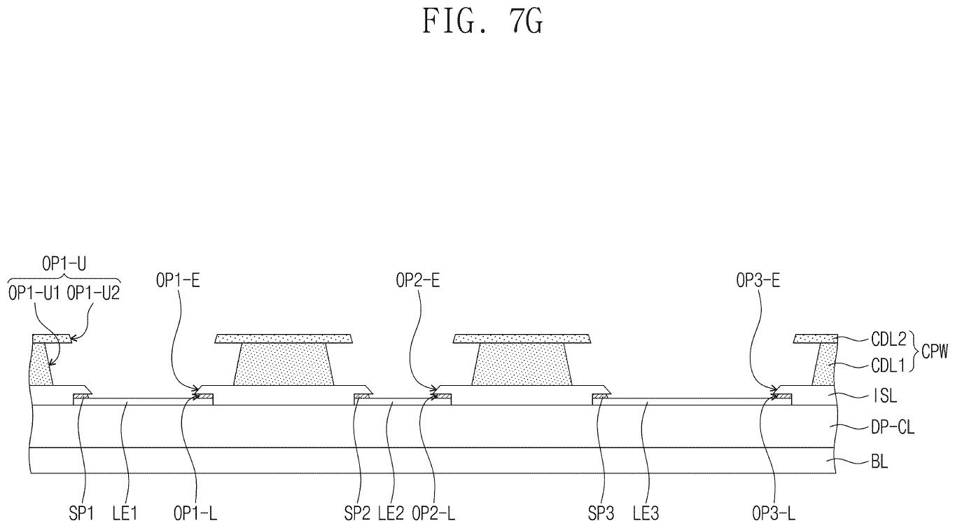

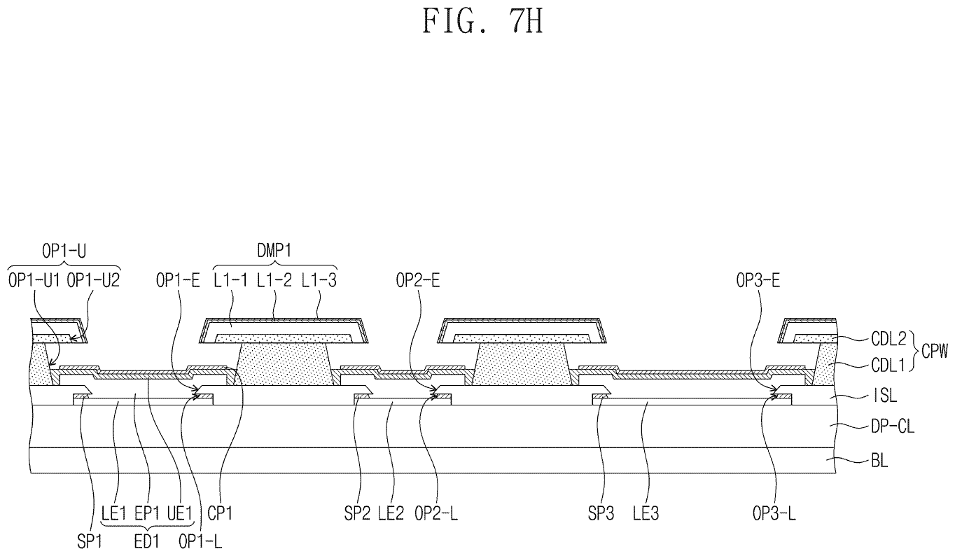

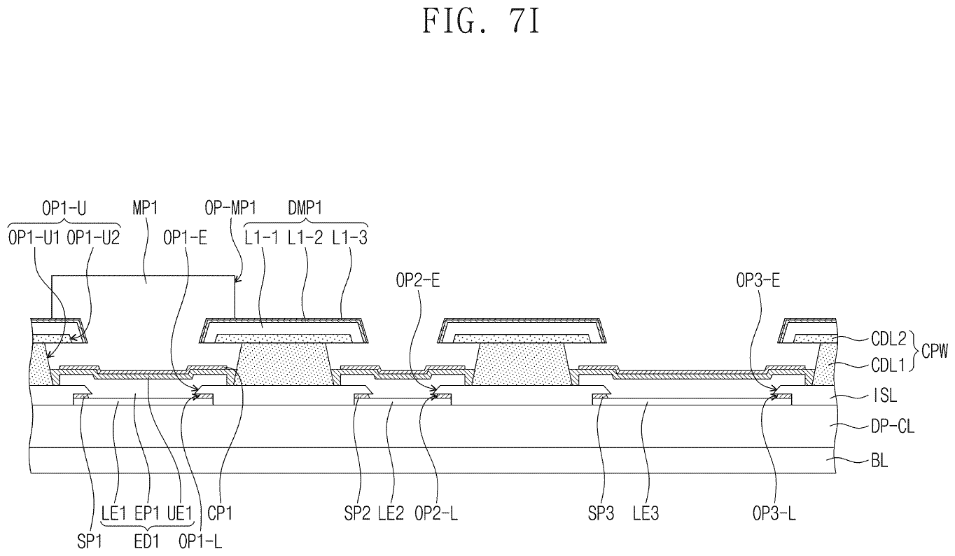

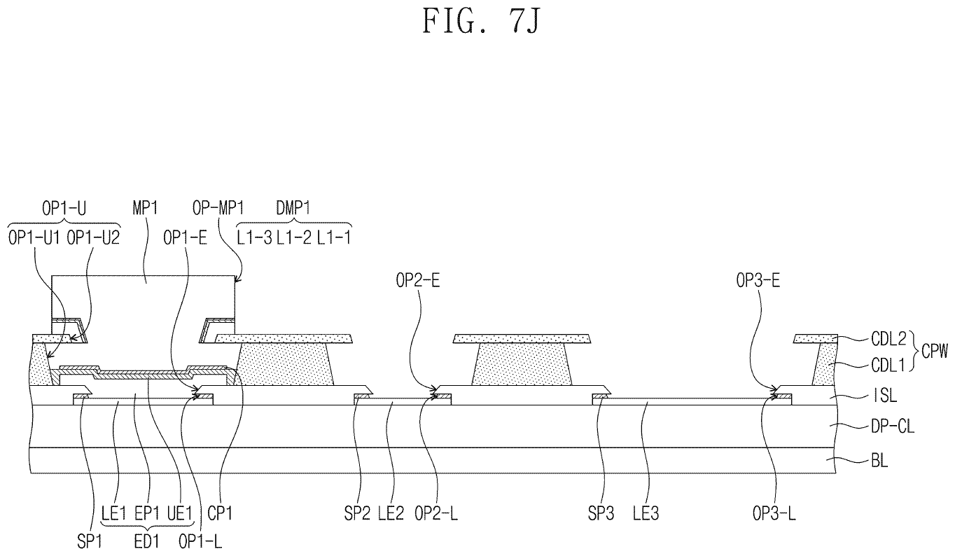

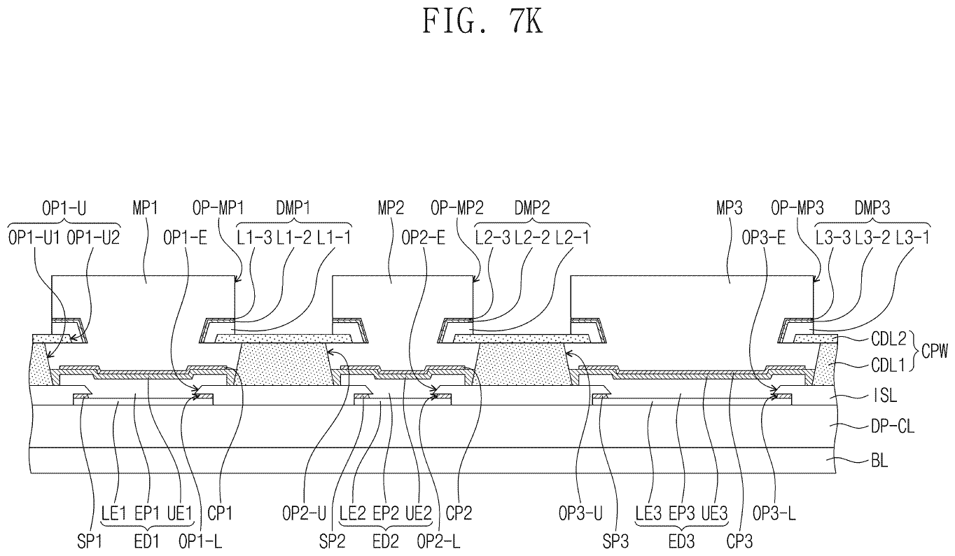

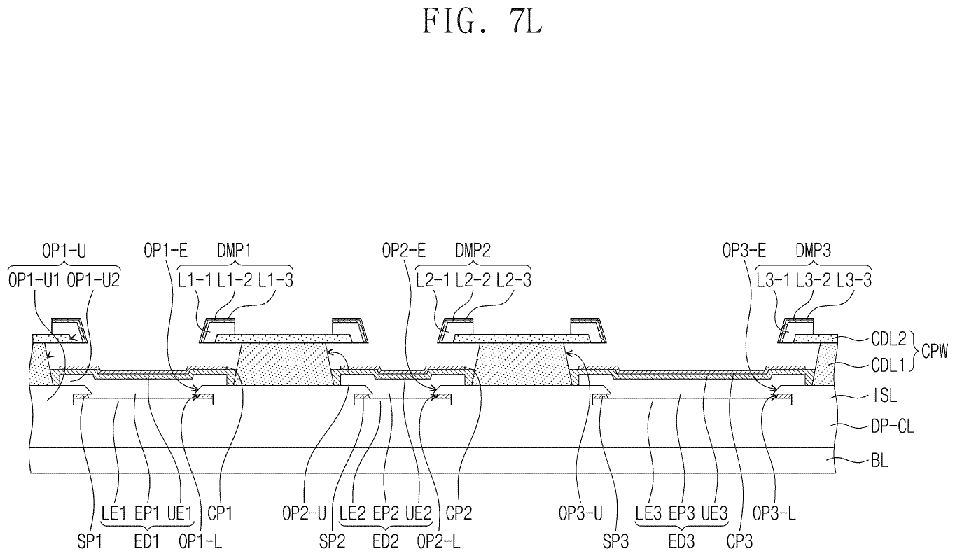

As described in more detail elsewhere herein, the dry etching process to form the conductive partition wall CPW may proceed after light-emitting openings OP1-E, OP2-E, and OP3-E are provided or formed in the insulation film ISL. In embodiments, the first to third sacrificial patterns SP1, SP2, and SP3 may be exposed to the outside and may react with a chlorine-containing gas to dry etch. If the first to third sacrificial patterns SP1, SP2, and SP3 include indium, indium may react with chlorine included in the etching gas to thereby provide or form indium chloride which is highly corrosive and has a high volatilization temperature. This may cause corrosion of the chamber. Accordingly, in some embodiments, the first to third sacrificial patterns SP1, SP2, and SP3 may exclude (may not contain) indium, or if any, may include (contain) a trace amount (e.g., less than 0.01 wt %) of indium. This will be described in more detail with reference to FIGS. 7A to 7L which illustrate a manufacturing method of a display device.

The first to third sacrificial patterns SP1, SP2, and SP3 may be doped with aluminum. In each of the first to third sacrificial patterns SP1, SP2, and SP3, an atomic percent of aluminum may be about 1 at % to about 5 at %. When the atomic percent of aluminum in the first to third sacrificial patterns SP1, SP2, and SP3 is more than about 5 at %, a sintered state may be unstable and cracks may occur during the formation of the first to third sacrificial patterns SP1, SP2, and SP3, thereby making a manufacturing process difficult. When the atomic percent of aluminum in the first to third sacrificial patterns SP1, SP2, and SP3 is less than about 1 at %, conductivity of the first to third sacrificial patterns SP1, SP2, and SP3 may be lowered (may not be suitable).

The first to third sacrificial patterns SP1, SP2, and SP3 may each include at least one selected from among gallium oxide, zinc oxide, and tin oxide. Accordingly, corrosion of the chamber may not occur (e.g., even) when reacting with the chlorine-containing gas during the dry etching process to form the conductive partition wall CPW.

For example, gallium chloride (GaCl₃), which is generated when gallium oxide reacts with chlorine, may have a volatilization temperature as low as about minus 35 centigrade degrees (−35° C.), and thus volatilize during the dry etching process. Tin chloride (SnCl₄) which is generated when tin oxide reacts with chlorine may have a volatilization temperature as low as about minus 100 centigrade degrees (−100° C.), and thus volatilize during the dry etching process, as well. Zinc chloride (SnCl-₂) which is generated when zinc oxide reacts with chlorine may have a volatilization temperature as high as about 230 centigrade degrees (230° C.), and thus remain in the chamber during the dry etching process. However, zinc chloride has low corrosivity and may not corrode the chamber. The zinc chloride remaining in the chamber may be periodically removed.

The first to third sacrificial patterns SP1, SP2, and SP3 may each include gallium zinc oxide and/or zinc tin oxide. The first to third sacrificial patterns SP1, SP2, and SP3 may each include aluminum-doped gallium zinc oxide (AGZO) and/or aluminum-doped zin tin oxide.

A thickness T3 of the first sacrificial pattern SP1 may be about 100 angstroms (Å) to about 300 angstroms (Å). When the thickness T3 of the first sacrificial pattern SP1 is more than about 300 Å, an angle of the first sacrificial pattern SP1 may become too large, thereby causing a risk of decoupling or disconnection in the first light-emitting pattern EP1, the first upper electrode UI, and/or the like, which are on the first lower electrode LE1. When the thickness T3 of the first sacrificial pattern SP1 is less than about 100 Å, the first sacrificial pattern SP1 may not protect the first lower electrode LE1 during the etching process. The description of the thickness T3 of the first sacrificial pattern SP1 will be similarly applied to the second sacrificial pattern SP2 and the third sacrificial pattern SP3.

The insulation film ISL may be on the sixth insulation layer 60 of the circuit element layer DP-CL. The insulation film ISL may cover the first to third lower electrodes LE1, LE2, and LE3, and the first to third sacrificial patterns SP1, SP2, and SP3. For example, the insulation film ISL may cover a top surface of each of the first to third sacrificial patterns SP1, SP2, and SP3.

The first to third light-emitting openings OP1-E, OP2-E, and OP3-E may be provided (defined) in the insulation film ISL. The first light-emitting opening OP1-E may correspond to the first lower opening OP1-L of the first sacrificial pattern SP1, the second light-emitting opening OP2-E may correspond to the second lower opening OP2-L of the second sacrificial pattern SP2, and the third light-emitting opening OP3-E may correspond to the third lower opening OP3-L of the third sacrificial pattern SP3.

According to this embodiment, on a plane, the first light-emitting opening OP1-E may overlap the first lower opening OP1-L, and an area of the first light-emitting opening OP1-E may be smaller than an area of the first lower opening OP1-L. For example, an inner surface of the insulation film ISL, which provides or defines the first light-emitting opening OP1-E, may be closer (more adjacent) to a center of the first lower electrode LE1 than to an inner surface of the first sacrificial pattern SP1, which provides or defines the first lower opening OP1-L. In embodiments, a portion of the insulation film ISL, which is closer (more adjacent) to the center of the first lower electrode LE1 than to the inner surface of the first sacrificial pattern SP1 providing or defining the first lower opening OP1-L, may provide or define a tip-portion. The description of the first light-emitting opening OP1-E and the first lower opening OP1-L may be similarly applied to the second light-emitting opening OP2-E and the second lower opening OP2-L, and the third light-emitting opening OP3-E and the third lower opening OP3-L.

The insulation film ISL may include an inorganic insulating material, and for example, may include silicon nitride (SiNx and 0<x<about 1.4). The insulation film ISL may be between the first to third lower electrodes LE1, LE2, and LE3 and the conductive partition wall CPW, and thus may block the first to third lower electrodes LE1, LE2, and LE3 and the conductive partition wall CPW from being electrically coupled or connected to each other.

An angle θ of the inner surface provides or defines the first light-emitting opening OP1-E of the insulation film ISL, and may be a gentle angle. This makes it possible to reduce a risk of disconnection in the first light-emitting pattern EP1, the first upper electrode UE1, and/or the like, which are on the first lower electrode LE1, due to the excessively large angle θ of the inner surface of the insulation film ISL. To this end, the light-emitting openings OP1-E, OP2-E, and OP3-E of the insulation film ISL may be provided or formed first before providing or forming the conductive partition wall CPW. This will be described in more detail with reference to FIGS. 7A to 7L which illustrate a manufacturing method of a display device.

The conductive partition wall CPW may be on the insulation film ISL. First to third upper openings OP1-U, OP2-U, and OP3-U may be provided or defined in the conductive partition wall CPW. The first upper opening OP1-U may correspond to the first light-emitting opening OP1-E, the second upper opening OP2-U may correspond to the second light-emitting opening OP2-E, and the third upper opening OP3-U may correspond to the third light-emitting opening OP3-E.

In one or more embodiments, the conductive partition wall CPW may include a first conductive layer CDL1 and a second conductive layer CDL2. The first conductive layer CDL1 and the second conductive layer CDL2 may each include a conductive material. The first conductive layer CDL1 may be on the insulation film ISL, and may have a first conductivity and a first thickness TT1. The second conductive layer CDL2 may be on the first conductive layer CDL1, may have a second conductivity less (lower) than the first conductivity, and may have a second thickness TT2 smaller than the first thickness.

An etch rate of the first conductive layer CDL1 may be greater than an etch rate of the second conductive layer CDL2. For example, the first conductive layer CDL1 may include a material with a higher etch selectivity than the second conductive layer CDL2.

In one or more embodiments, the first and second conductive layers CDL1 and CDL2 may each include a metal material. In one or more embodiments, the second conductive layer CDL2 may include a material with lower reflectance than the first conductive layer CDL1, and may enhance or improve the display quality of the display panel DP by reducing the reflectance at a top surface of the second conductive layer CDL2 which substantially includes or constitutes a top surface US_CPW of the conductive partition wall CPW. For example, the first conductive layer CDL1 may include aluminum (Al), and the second conductive layer CDL2 may include titanium (Ti). However, materials of the first and second conductive layers CDL1 and CDL2 are not limited to any one embodiment.

In one or more embodiments, the conductive partition wall CPW may receive a bias voltage. Accordingly, the bias voltage may be provided to each of the first to third upper electrodes UE1, UE2, and UE3 on (e.g., contacting) the conductive partition wall CPW.

In one or more embodiments, on a plane, the first upper opening OP1-U provided or defined in the second conductive layer CDL2 may overlap the first upper opening OP1-U provided or defined in the first conductive layer CDL1, and an area of the first upper opening OP1-U provided or defined in the second conductive layer CDL2 may be smaller than an area of the first upper opening OP1-U provided or defined in the first conductive layer CDL1.

As illustrated in FIG. 5A, on a cross-section, the first upper opening OP1-U may include a first region OP1-U1 provided or defined by an inner surface of the first conductive layer CDL1 and a second region OP1-U2 provided or defined by an inner surface of the second conductive layer CDL2. On a cross-section, a width of the first region OP1-U1 may be greater than a width of the second region OP1-U2. On a cross-section, the inner surface of the second conductive layer CDL2, which provides or defines the second region OP1-U2, may be closer (more adjacent) to the center of the first lower electrode LE1 than to the inner surface of the first conductive layer CDL1, which provides or defines the first region OP1-U1. According to embodiments of the present disclosure, in the conductive partition wall CPW, a portion of the second conductive layer CDL2, which is closer (more adjacent) to the center of the first lower electrode LE1 than to the inner surface of the first conductive layer CDL1 providing or defining the first region OP1-U1, may be provided or defined as a tip-portion. In embodiments, a length of the portion corresponding to the tip-portion may be substantially the same throughout all regions, e.g., first region, second region, and/or the like. For example, distances WD1, WD2, and WD3 between the inner surfaces of the first conductive layer CDL1 and the inner surfaces of the second conductive layer CDL2 may be substantially the same throughout all regions, e.g., first region, second region, and/or the like.

According to one or more embodiments, on a plane, an area of the first upper opening OP1-U1 provided or defined in the first conductive layer CDL1 may be greater than an area of the first light-emitting opening OP1-E provided or defined in the insulation film ISL, and the first conductive layer CDL1 may expose a portion of a top surface of the insulation film ISL due to the first upper opening OP1-U1.

The first to third light-emitting patterns EP1, EP2, and EP3 may be respectively on corresponding lower electrodes among the first to third lower electrodes LE1, LE2, and LE3. The first light-emitting pattern EP1 may be on the first upper electrode UE1, the second light-emitting pattern EP2 may be on the second upper electrode UE2, and the third light-emitting pattern EP3 may be on the third upper electrode UE3. In one or more embodiments, the first light-emitting pattern EP1 may provide red light, the second light-emitting pattern EP2 may provide green light, and the third light-emitting pattern EP3 may provide blue light.

The first to third light-emitting patterns EP1, EP2, and EP3 may each include a light-emitting layer having a light-emitting material. Each of the first to third light-emitting patterns EP1, EP2, and EP3 may further include a hole injection layer HIL and a hole transport layer HTL which are between the light-emitting layer and the corresponding lower electrode among the first to third lower electrodes LE1, LE2, and LE3, and may further include an electron transport layer ETL and an electron injection layer EIL which are on the light-emitting layer. Each of the first to third light-emitting patterns EP1, EP2, and EP3 may also be referred to as an ‘organic pattern’.

According to embodiments of the present disclosure, the first to third light-emitting patterns EP1, EP2, and EP3 may be patterned by the tip-portion provided or defined in the conductive partition wall CPW. The first light-emitting pattern EP1 may be inside the first lower opening OP1-L, the first light-emitting opening OP1-E, and the first upper opening OP1-U. The first light-emitting pattern EP1 may cover a portion of the top surface of the insulation film ISL which is exposed from the first upper opening OP1-U. The second light-emitting pattern EP2 may be inside the second lower opening OP2-L, the second light-emitting opening OP2-E, and the second upper opening OP2-U. The second light-emitting pattern EP2 may cover a portion of the top surface of the insulation film ISL which is exposed from the second upper opening OP2-U. The third light-emitting pattern EP3 may be inside the third lower opening OP3-L, the third light-emitting opening OP3-E, and the third upper opening OP3-U. The third light-emitting pattern EP3 may cover a portion of the top surface of the insulation film ISL which is exposed from the third upper opening OP3-U.

According to embodiments of the present disclosure, the plurality of first light-emitting patterns EP1 may be patterned and deposited in units of a pixel by the tip-portion defined in the conductive partition wall CPW. For example, the plurality of first light-emitting patterns EP1 may be provided or formed in common by using an open mask, but may be easily divided into the units of the pixel by the conductive partition wall CPW.

In contrast, when the plurality of first light-emitting patterns EP1 are patterned by using a separate mask (for example, a fine metal mask (FMM)), a supporting spacer protruding from a partition wall should be provided so as to support the separate mask. In some embodiments, because the separate mask is spaced and/or apart (e.g., spaced apart or separated) by a height of the partition wall and the spacer from the base surface on which the patterning is performed, there may be limitations in improvement of resolution.

In some embodiments, because the mask is in contact with the spacer, foreign matters may remain on the spacer after the patterning process of the plurality of first light-emitting patterns EP1, and the spacer that is damaged by being dented by the mask may be provided. Accordingly, a defective display panel may be provided or formed.

According to embodiments of the present disclosure, because the plurality of first light-emitting patterns EP1 are patterned without a separate mask contacting internal components of the display panel DP, a defect rate may be reduced and the display panel DP with enhanced or improved reliability may be provided. In embodiments, production of a large-sized mask may be avoided or omitted in manufacture of the large-sized display panel DP to thereby reduce process costs, and the display panel DP with improved reliability may be provided because of not being affected by a defect which may occur in the large-sized mask.

According to embodiments of the present disclosure, as illustrated in FIG. 5A, a thickness T1 of the first light-emitting pattern EP1 may be greater than a sum T2 of T3, (the thickness of the first sacrificial pattern SP1) and a thickness of the insulation film ISL. In this specification, a ‘thickness of a light-emitting pattern’ refers to an average thickness at a portion of the first light-emitting pattern EP1 on (e.g., in contact with) the top surface of the first lower electrode LE1. A ‘thickness of a sacrificial pattern’ refers to an average thickness at a portion of the first sacrificial pattern SP1 on (e.g., in contact with) the top surface of the first lower electrode LE1, and a ‘thickness of an insulation film’ refers to an average thickness at a portion of the insulation film ISL on (e.g., in contact with) the top surface of the first sacrificial pattern SP1.

This may prevent the first light-emitting pattern EP1 from being separated at a portion of the first light-emitting pattern EP1 covering the inner surface of the first sacrificial pattern SP1 that provides or defines the first lower opening OP1-L. Accordingly, the defective first light-emitting pattern EP1 may be prevented from being provided or formed, and the first light-emitting element ED1 with improved reliability may be provided.

FIG. 5A illustrates an example in which the first light-emitting pattern EP1 is not on (e.g., in contact with) the inner surface of the first conductive layer CDL1 which defines the first upper opening OP1-U, but one or more embodiments of the present disclosure is not limited thereto. For example, the first light-emitting pattern EP1 may be on (e.g., in contact with) the inner surface of the first conductive layer CDL1 which provides or defines the first upper opening OP1-U.

The description of the aforementioned first light-emitting pattern EP1 may be similarly applied to the second and third light-emitting patterns EP2 and EP3.

The first to third upper electrodes UE1, UE2, and UE3 may be respectively on corresponding light-emitting patterns among the first to third light-emitting patterns EP1, EP2, and EP3. The first upper electrode UI may be on the first light-emitting pattern EP1, the second upper electrode UE2 may be on the second light-emitting pattern EP2, and the third upper electrode UE3 may be on the third light-emitting pattern EP3. The first to third upper electrodes UE1, UE2, and UE3 may be patterned by the tip-portion provided or defined in the conductive partition wall CPW.

According to embodiments of the present disclosure, the first upper electrode UI may be on (e.g., in contact with) the inner surface of the first conductive layer CDL1 which provides or defines the first region OP1-U1 of the first upper opening OP1-U. Accordingly, the first upper electrode UI may be electrically coupled or connected to the conductive partition wall CPW, and may receive a bias voltage via the conductive partition wall CPW.

According to embodiments of the present disclosure, because the first upper electrode UI is on the first light-emitting pattern EP1 which has a thickness greater than the thicknesses of the first sacrificial pattern SP1 and the insulation film ISL, the first upper electrode UI may be provided or formed not to be separated from the inside of the first upper opening OP1-U. Thus, a portion of the first upper electrode UE1, which is electrically disconnected from the conductive partition wall CPW, may not be provided or formed, so that providing the defective first light-emitting element ED1 may be prevented. The description of the aforementioned first upper electrode UI may be similarly applied to the second and third upper electrodes UE2 and UE3.

In some embodiments of the present disclosure, because the first to third upper electrodes UE1, UE2, and UE3 are not provided as common layers overlapping all the first to third light-emitting patterns EP1, EP2, and EP3, a lateral leakage current occurring through the common layers may be avoided (may not occur). In some embodiments, because the upper electrodes UE1, UE2, and UE3 are electrically connected to the conductive partition wall CPW having a relatively great thickness and a driving resistance is reduced or lowered, the first to third light-emitting elements ED1, ED2 and ED3 with increased light-emitting efficiency and an increased life span may be provided.

Capping patterns CP1, CP2, and CP3 may include a first capping pattern CP1 on the first upper electrode UI inside the first upper opening OP1-U, a second capping pattern CP2 on the second upper electrode UE2 inside the second upper opening OP2-U, and a third capping pattern CP3 on the third upper electrode UE3 inside the third upper opening OP3-U. The first to third capping patterns CP1, CP2, and CP3 may be provided or patterned by the tip-portion defined in the conductive partition wall CPW. According to another embodiment of the present disclosure, the first to third capping patterns CP1, CP2, and CP3 may not be provided.

FIGS. 5A and 5B illustrate examples having the first capping pattern CP1 to not be on (e.g., in contact with) the inner surface of the first conductive layer CDL1 which provides or defines the first upper opening OP1-U, but one or more embodiments of the present disclosure is not limited thereto. For example, the first capping pattern CP1 may be provided or formed to be on (e.g., in contact with) the inner surface of the first conductive layer CDL1 which provides or defines the first upper opening OP1-U.

The dummy patterns DMP1, DMP2, and DMP3 may be on the conductive partition wall CPW. The dummy patterns DMP1, DMP2, and DMP3 may include a first dummy pattern DMP1, a second dummy pattern DMP2, and a third dummy pattern DMP3.

As illustrated in FIG. 5B, the first dummy pattern DMP1 may cover a portion of the top surface US_CPW of the conductive partition wall CPW. The first dummy pattern DMP1 may cover at least a portion of the inner surface of the second conductive layer CDL2 which provides or defines the first upper opening OP1-U. A portion of the first dummy pattern DMP1 may overlap the inner surface of the second conductive layer CDL2 which provides or defines the second region OP1-U2.

As illustrated in FIG. 5A, the first dummy pattern DMP1 may include a dummy organic layer L1-1, a dummy conductive layer L1-2, and a dummy capping layer L1-3.

The dummy organic layer L1-1 and the first light-emitting pattern EP1 may be provided or formed through substantially the same process, and thus have substantially the same structure and include substantially the same material. The dummy organic layer L1-1 may be spaced and/or apart (e.g., spaced apart or separated) from the first to third light-emitting patterns EP1, EP2, and EP3. The dummy organic layer L1-1 may correspond to a residue separated from the first light-emitting pattern EP1 by the conductive partition wall CPW when providing or forming the first light-emitting pattern EP1 in common.

The dummy conductive layer L1-2 may be on the dummy organic layer L1-1. The dummy conductive layer L1-2 and the first upper electrode UE1 may be provided or formed through substantially the same process and thus have substantially the same structure and include substantially the same material. The dummy conductive layer L1-2 may be spaced and/or apart (e.g., spaced apart or separated) from the first to third upper electrodes UE1, UE2, and UE3. The dummy conductive layer L1-2 may correspond to a residue separated from the first upper electrode UI by the conductive partition wall CPW when forming the first upper electrode UI in common.

The dummy capping layer L1-3 may be on the dummy conductive layer L1-2. The dummy capping layer L1-3 and the first capping pattern CP1 may be provided or formed through substantially the same process and thus have substantially the same structure and include substantially the same material. The dummy capping layer L1-3 may be spaced and/or apart (e.g., spaced apart or separated) from the first to third capping patterns CP1, CP2, and CP3. The dummy capping layer L1-3 may correspond to a residue separated from the first capping pattern CP1 by the conductive partition wall CPW when forming the first capping pattern CP1 in common.

The description of the first dummy pattern DMP1 may be similarly applied to the second dummy pattern DMP2 and the third dummy pattern DMP3. The second dummy pattern DMP2 may include a dummy organic layer L2-1, a dummy conductive layer L2-2, and a dummy capping layer L2-3. The third dummy pattern DMP3 may include a dummy organic layer L3-1, a dummy conductive layer L3-2, and a dummy capping layer L3-3.

The thin-film encapsulation layer TFE may be on the display element layer DP-OLED. The thin-film encapsulation layer TFE may include a lower inorganic encapsulation film LIL, an organic encapsulation film OL, and an upper inorganic encapsulation film UIL.

The lower inorganic encapsulation film LIL may be provided or formed on the conductive partition wall CPW and the upper electrodes UE1, UE2, and UE3. For example, the lower inorganic encapsulation film LIL may cover the dummy patterns DMP1, DMP2, and DMP3 and the upper electrodes UE1, UE2, and UE3 (or the capping patterns CP1, CP2, and CP3). In some embodiments, the lower inorganic encapsulation film LIL may be on (e.g., in contact with) the inner surface of the first conductive layer CDL1 which provides or defines the upper openings OP1-U, OP2-U, and OP3-U.

The organic encapsulation film OL may be on the lower inorganic encapsulation film LIL, and may include an organic material. The organic encapsulation film OL may have a flat top surface. The upper inorganic encapsulation film UIL may be on the organic encapsulation film OL.

The lower inorganic encapsulation film LIL and the upper inorganic encapsulation film UIL may protect the display element layer DP-OLED from moisture and/or oxygen, and the organic encapsulation film OL may protect the display element layer DP-OLED from foreign matters such as dust particles and/or the like.

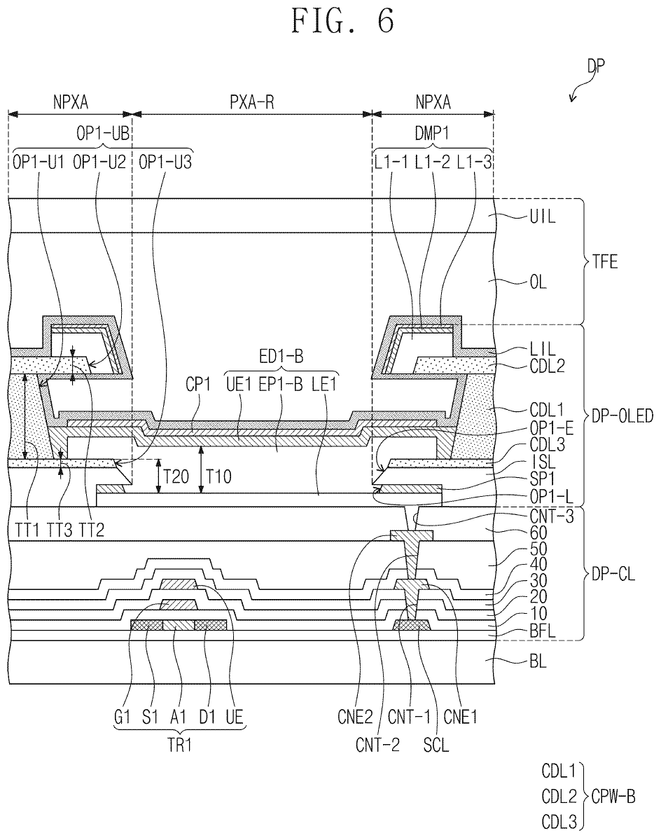

FIG. 6 is an enlarged cross-sectional view of a portion of a display panel according to one or more embodiments of the present disclosure. Hereinafter, components that are substantially the same as the components described with reference to FIGS. 5A and 5B will be denoted as the same reference numerals or symbols, and a duplicate explanation thereof will not be provided.

Referring to FIG. 6, a display element layer DP-OLED according to one or more embodiments may include a first light-emitting element ED1-B, a first sacrificial pattern SP1, an insulation film ISL, a conductive partition wall CPW-B, and a first dummy pattern DMP1. The first light-emitting element ED1-B may include a first lower electrode LE1, a first light-emitting pattern EP1-B, and a first upper electrode UE1.

In this embodiment, the conductive partition wall CPW-B may include a first conductive layer CDL1, a second conductive layer CDL2, and a third conductive layer CDL3. The third conductive layer CDL3 may be under the first conductive layer CDL1. The third conductive layer CDL3 may have a third conductivity lower than a first conductivity, and may have a third thickness TT3 less (smaller) than a first thickness TT1. FIG. 6 illustrates that the third thickness TT3 is less (smaller) than a second thickness TT2, but this is merely an example for illustrative purposes. The third thickness TT3 may be substantially the same as the second thickness TT2.

The third conductive layer CDL3 may include a conductive material. In one or more embodiments, the third conductive layer CDL3 may include substantially the same material as the second conductive layer CDL2, and the first conductive layer CDL1 may include a material different from those of the second and third conductive layers CDL2 and CDL3. For example, the second and third conductive layers CDL2 and CDL3 may include titanium (Ti), and the first conductive layer CDL1 may include aluminum (Al). In embodiments, the third conductivity may be substantially the same as a second conductivity. In one or more embodiments, the third conductive layer CDL3 may include a material that has greater adhesive force to the insulation film ISL than the second conductive layer CDL2. Accordingly, the conductive partition wall CPW-B may be coupled or attached to the insulation film ISL with greater adhesive force, and the conductive partition wall CPW-B with enhanced or improved process reliability may be provided, and therefore the reliability of the light emitting elements ED1-B, which include the light-emitting patterns EP1-B and the upper electrodes UI patterned by the conductive partition wall CPW-B, may also be enhanced or improved.

An etch rate of the third conductive layer CDL3 may be less (smaller) than an etch rate of the first conductive layer CDL1. For example, the first conductive layer CDL1 may include a material with a greater (higher) etch selectivity than the third conductive layer CDL3.

On a cross-section, a first upper opening OP1-UB may include a first region OP1-U1 provided or defined by an inner surface of the first conductive layer CDL1, a second region OP1-U2 provided or defined by an inner surface of the second conductive layer CDL2, and a third region OP1-U3 provided or defined by an inner surface of the third conductive layer CDL3. For example, in this embodiment, the first upper opening OP1-UB may further include the third region OP1-U3.

On a cross-section, a width of the third region OP1-U3 may be less (smaller) than a width of the first region OP1-U1 and/or a width of the second region OP1-U2. On a cross-section, the inner surface of the third conductive layer CDL3, which provides or defines the third region OP1-U3, may be closer (more adjacent) to a center of the first lower electrode LE1 than to the inner surface of the first conductive layer CDL1, which provides or defines the first region OP1-U1, and the inner surface of the second conductive layer CDL2, which provides or defines the second region OP1-U2.

In this embodiment, because the conductive partition wall CPW-B further includes the third conductive layer CDL3, a portion of the first light-emitting pattern EP1-B may be on a top surface of the third conductive layer CDL3 which is exposed from the first conductive layer CDL1. Accordingly, a thickness T10 of the first light-emitting pattern EP1-B may be designed to be greater than a sum T20 of a thickness of the first sacrificial pattern SP1, a thickness of the insulation film ISL, and a thickness of the third conductive layer CDL3.

FIGS. 7A to 7L are cross-sectional views illustrating some steps of a manufacturing method of a display device according to one or more embodiments of the present disclosure.

Referring to FIG. 7A, the method may include a step of providing or patterning first to third lower electrodes LE1, LE2, and LE3 and first to third sacrificial patterns SP1, SP2, and SP3 onto a base substrate. In this embodiment, the base substrate may include a base layer BL and a circuit element layer DP-CL on the base layer BL. The circuit element layer DP-CL may be provided or formed through a suitable circuit element manufacturing process in which an insulation layer, a semiconductor layer, and a conductive layer are provided or formed through coating, deposition, and/or the like, and then the insulation layer, the semiconductor layer, and the conductive layer are selectively provided or patterned through a photolithography and etching process to form a semiconductor pattern, a conductive pattern, a signal line, and/or the like.

The first to third lower electrodes LE1, LE2, and LE3 may be provided or formed on the sixth insulation layer 60 (see FIG. 5A) of the circuit element layer DP-CL, and the first to third sacrificial patterns SP1, SP2, and SP3 may be respectively provided or formed on the first to third lower electrodes LE1, LE2, and LE3. The first to third lower electrodes LE1, LE2, and LE3 and the first to third sacrificial patterns SP1, SP2, and SP3 may be provided or formed through substantially the same patterning process.

Referring to FIG. 7B, the manufacturing method of the display device may include a step of providing or forming an insulation film ISL on the base substrate. The insulation film ISL may be provided or formed on the sixth insulation layer 60 (see FIG. 5A) of the circuit element layer DP-CL, and may cover the first to third lower electrodes LE1, LE2, and LE3 and the first to third sacrificial patterns SP1, SP2, and SP3. A preliminary display panel including the base layer BL, the lower electrodes LE1, LE2, and LE3, the sacrificial patterns SP1, SP2, and SP3, and the insulation film ISL may be provided through the steps illustrated in FIGS. 7A and 7B.

Referring to FIG. 7C, first to third light-emitting openings OP1-E, OP2-E, and OP3-E may be provided or formed in the insulation film ISL. The first light-emitting opening OP1-E may correspond to the first lower electrode LE1, the second light-emitting opening OP2-E may correspond to the second lower electrode LE2, and the third light-emitting opening OP3-E may correspond to the third lower electrode LE3. Dry etching may be performed to provide or form the first to third light-emitting openings OP1-E, OP2-E, and OP3-E in the insulation film ISL. A mask in which openings corresponding to the first to third light-emitting openings OP1-E, OP2-E, and OP3-E are provided or defined may be used.

In this way, the first to third light-emitting openings OP1-E, OP2-E, and OP3-E may be provided or formed in the insulation film ISL before providing or forming first and second conductive layers CDL1 and CDL2 (see FIG. 7D). A dry etching process may be performed in a state in which a stacked structure is excluded (not present) on the insulation film ISL, and the shapes of the first to third light-emitting openings OP1-E, OP2-E, and OP3-E of the insulation film ISL may be selected or adjusted more easily. For example, an angle of an inner surface of the insulation film ISL which provides or defines each of the first to third light-emitting openings OP1-E, OP2-E, and OP3-E may be prevented from becoming excessively large.

Referring to FIG. 7D, a conductive partition wall layer CPW-I may be provided or formed on the insulation film ISL in which the first to third light-emitting openings OP1-E, OP2-E, and OP3-E are provided or formed. The conductive partition wall layer CPW-I may include a first conductive layer CDL1 and a second conductive layer CDL2 provided or formed on the first conductive layer CDL1. The first conductive layer CDL1 may have a first conductivity and a first thickness TT1 (see FIG. 5A), and the second conductive layer CDL2 may have a second conductivity less (lower) than the first conductivity and a second thickness TT2 (see FIG. 5A) less (smaller) than the first thickness.

Referring to FIGS. 7E and 7F, an upper opening OP1-U corresponding to each of the first to third light-emitting openings OP1-E, OP2-E, and OP3-E may be provided or formed in the conductive partition wall layer CPW-I.

Referring to FIG. 7E, a preliminary upper opening including a first region OP1-U1 of the upper opening OP1-U (see FIG. 7F) corresponding to each of the first to third light-emitting openings OP1-E, OP2-E, and OP3-E may be provided or formed by etching the first conductive layer CDL1 and the second conductive layer CDL2 by using (through) dry etching. A chlorine-containing etching gas may be used in the dry etching process. In embodiments, because the first to third light-emitting openings OP1-E, OP2-E, and OP3-E have already been formed, the exposed first to third sacrificial patterns SP1, SP2, and SP3 may be exposed to the etching gas and a chemical reaction may occur. However, the first to third sacrificial patterns SP1, SP2, and SP3 according to one or more embodiments of the present disclosure may exclude (not include) indium or include a trace amount of indium (e.g., less than 0.01 wt %), so that etching byproducts such as indium chloride (InCl₃) corroding a chamber may not be produced.

Referring to FIG. 7F, the upper opening OP1-U may be provided or formed from the preliminary upper opening by etching the first conductive layer CDL1 and the second conductive layer CDL2 by using (through) wet etching. For example, the first region OP1-U1 and a second region OP1-U2 corresponding to each of the first to third light-emitting openings OP1-E, OP2-E, and OP3-E may be provided or formed.

In the wet etching process of the first and second conductive layers CDL1 and CDL2, an etch rate of the first conductive layer CDL1 with respect to an etching solution may be greater than an etch rate of the second conductive layer CDL2, and thus the first conductive layer CDL1 may be primarily etched. Accordingly, after the wet etching is completed, on a cross-section, an inner surface of the second conductive layer CDL2, which provides or defines the second region OP1-U2 of the first upper opening OP1-U, may be closer (more adjacent) to a center of each of the first to third lower electrodes LE1, LE2, and LE3 than to an inner surface of the first conductive layer CDL1 which provides or defines the first region OP1-U1 of the first upper opening OP1-U. A tip-portion may be provided or formed in the second conductive layer CDL2 of a conductive partition wall CPW.

Referring to FIG. 7G, lower openings OP1-L, OP2-L, and OP3-L may be provided or formed in the respective sacrificial patterns SP1, SP2, and SP3 by using (through) a wet etching process. In embodiments, the wet etching process may be performed by using the insulation film ISL as a mask. The first to third lower openings OP1-L, OP2-L, and OP3-L may be respectively provided or formed to have larger areas than the areas of the corresponding first to third light-emitting openings OP1-E, OP2-E, and OP3-E. A tip-portion may be provided or formed in the insulation film ISL.

According to embodiments of the present disclosure, due to material properties of the sacrificial patterns SP1, SP2, and SP3 and/or the lower electrodes LE1, LE2, and LE3, etch rates of the lower electrodes LE1, LE2, and LE3 with respect to an etching solution may be very much less (lower) than etch rates of the sacrificial patterns SP1, SP2, and SP3. Accordingly, the lower electrodes LE1, LE2, and LE3 may be prevented from being etched together during the etching process of the sacrificial patterns SP1, SP2, and SP3. For example, because the sacrificial patterns SP1, SP2, and SP3 including a material having a higher selectivity than the lower electrodes LE1, LE2, and LE3 are between the respective lower electrodes LE1, LE2, and LE3 and the insulation film ISL, the lower electrodes LE1, LE2, and LE3 may be prevented from being etched together and damaged during the etching process.

Referring to FIG. 7H, a first light-emitting pattern EP1, a first upper electrode UE1, and a first capping pattern CP1 may be provided or formed inside the first upper opening OP1-U, the first light-emitting opening OP1-E, and the first lower opening OP1-L. First dummy patterns DMP1 may be provided or formed simultaneously (together) in the step of providing or forming the first light-emitting pattern EP1, the first upper electrode UE1, and the first capping pattern CP1. The first dummy patterns DMP1 may be deposited while being separated from each other by the tip-portion provided or defined in the conductive partition wall CPW, and thus be formed spaced and/or apart (e.g., spaced apart or separated) from each other.

The first dummy patterns DMP1 may each include an organic dummy layer L1-1, a dummy conductive layer L1-2, and a dummy capping layer L1-3. The dummy organic layer L1-1 and the first light-emitting pattern EP1 may be provided or formed through substantially the same process, and thus have substantially the same structure and include substantially the same material. The dummy conductive layer L1-2 and the first upper electrode UE1 may be provided or formed through substantially the same process, and thus have substantially the same structure and include substantially the same material. The dummy capping layer L1-3 and the first capping pattern CP1 may be provided or formed through substantially the same process, and thus have substantially the same structure and include substantially the same material.

The first light-emitting pattern EP1 may be provided or formed through a thermal evaporation process. When the first upper electrode UE1 is provided or formed, the first upper electrode may be provided or formed through a sputtering process. The first upper electrode UI may be provided at a higher incident angle than the first light-emitting pattern EP1 due to the nature of the process, and thus the first upper electrode UI may be provided or formed to on (e.g., be in contact with) the inner surface of the first conductive layer CDL1 which defines the first upper opening OP1-U. The first capping pattern CP1 may be provided or formed on the first upper electrode UI inside the first upper opening OP1-U.

Referring to FIGS. 7I and 7J, a first mask pattern MP1 in which a first mask opening OP-MP1 is provided or defined may be provided or formed through exposure and development. The first mask pattern MP1 may overlap the first upper opening OP1-U, the first light-emitting opening OP1-E, and the first lower opening OP1-L. Then, by using the first mask pattern MP1 as a mask, the stacked structures, which do not overlap the first mask pattern MP1 but respectively overlap the second and third light-emitting openings OP2-E and OP3-E formed through the process described with reference to FIG. 7H, may be etched.

Referring to FIG. 7K, through substantially the same process as the process described with reference to FIGS. 7H to 7J, a second light-emitting element ED2 overlapping the second light-emitting opening OP2-E and a third light-emitting element ED3 overlapping the third light-emitting opening OP3-E may be provided or formed. When providing or forming each of the second light-emitting element ED2 and the third light-emitting element ED3, a second dummy pattern DMP2 and a third dummy pattern DMP3 may be formed simultaneously. By using a second mask pattern MP2 in which a second mask opening OP-MP2 is provided or defined, a stacked structure that does not overlap the second mask pattern MP2 may be etched, and by using a third mask pattern MP3 in which a third mask opening OP-MP3 may be provided or defined, a stacked structure that does not overlap the third mask pattern MP3 may be etched.

Referring to FIG. 7L, the first to third mask patterns MP1, MP2, and MP3 (see FIG. 7K) may be removed.

In a display device according to embodiments of the present disclosure, because a sacrificial pattern excludes (e.g., does not include) indium, gas that corrodes a chamber may not be emitted during a dry etching step.

In a manufacturing method of a display device according to embodiments of the present disclosure, an insulation film may be patterned first, and then a conductive partition wall may be formed, thereby making it possible to pattern the insulation film into a desired shape.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display device and/or electronic device may be formed on one integrated circuit (IC) chip or on separate IC chips. Further, the one or more suitable components of the display device and/or electronic device may be implemented on a flexible printed circuit film, a tape carrier package (TCP), a printed circuit board (PCB), or formed on one substrate. Further, the one or more suitable components of the display device and/or electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

In the preceding, description has been made with reference to embodiments, but those skilled in the art or those of ordinary skill in the relevant technical field may understand that one or more suitable modifications and changes may be made to embodiments of the present disclosure within the scope not departing from the spirit and the technology scope of the present disclosure described in the claims to be described later. Therefore, the technical scope of the present disclosure is not limited to the contents described in the detailed description of the specification, but should be determined by the appended claims, and equivalents thereof.

What is claimed is:

1. A display device comprising:
a base layer;
a lower electrode on the base layer;
a sacrificial pattern on the lower electrode, and having a lower opening, the lower opening exposing a portion of a top surface of the lower electrode;
an insulation film on the base layer, the insulation film on at least a portion of the sacrificial pattern, and having a light-emitting opening corresponding to the lower opening; and
a conductive partition wall on the insulation film, and having an upper opening corresponding to the light-emitting opening,
wherein in the sacrificial pattern, an atomic percent of indium is less than about 0.1 at %.

2. The display device of claim 1, wherein the sacrificial pattern is doped with aluminum.

3. The display device of claim 2, wherein an atomic percent of aluminum in the sacrificial pattern is about 1 at % to about 5 at %.

4. The display device of claim 2, wherein the sacrificial pattern comprises at least one selected from among gallium oxide, zinc oxide, and tin oxide.

5. The display device of claim 2, wherein the sacrificial pattern comprises gallium zinc oxide or zinc tin oxide.

6. The display device of claim 2, wherein a thickness of the sacrificial pattern is about 100 angstroms (Å) to about 300 angstroms (Å).

7. The display device of claim 1, wherein the sacrificial pattern excludes indium.

8. The display device of claim 1, further comprising:
a light-emitting pattern, the light-emitting pattern inside the lower opening, the light-emitting opening, and the upper opening, and on the lower electrode; and
an upper electrode on the light-emitting pattern, and on an inner surface of the conductive partition wall, the inner surface comprising the upper opening.

9. The display device of claim 8, further comprising:
a lower inorganic encapsulation film on the upper electrode and the conductive partition wall;
an organic encapsulation film on the lower inorganic encapsulation film; and
an upper inorganic encapsulation film on the organic encapsulation film,
wherein the lower inorganic encapsulation film is on the inner surface of the conductive partition wall.

10. The display device of claim 9, further comprising a capping pattern between the upper electrode and the lower inorganic encapsulation film.

11. The display device of claim 1, wherein the conductive partition wall comprises a first conductive layer having a first conductivity, and a second conductive layer on the first conductive layer and having a second conductivity less than the first conductivity, and
a thickness of the first conductive layer is greater than a thickness of the second conductive layer.

12. The display device of claim 11, wherein
an inner surface of the first conductive layer has a first region of the upper opening,
an inner surface of the second conductive layer has a second region of the upper opening, and
the inner surface of the second conductive layer is closer to a center of the lower electrode than to the inner surface of the first conductive layer, based on a cross-section of the display device.

13. The display device of claim 12, wherein a distance between the inner surface of the first conductive layer and the inner surface of the second conductive layer in the first region is substantially equal to a distance between the inner surface of the first conductive layer and the inner surface of the second conductive layer in the second region.

14. An electronic device comprising:
a display module;
a window on the display module; and
a housing under the display module,
wherein the display module comprises:
a base layer;
a lower electrode on the base layer;
a sacrificial pattern on the lower electrode, and having a lower opening, the lower opening exposing a portion of a top surface of the lower electrode;
an insulation film on the base layer, the insulation film covering at least a portion of the sacrificial pattern, and having a light-emitting opening corresponding to the lower opening; and
a conductive partition wall on the insulation film, and having an upper opening corresponding to the light-emitting opening,
wherein the sacrificial pattern excludes indium.

15. A method comprising:
providing a preliminary display panel comprising a base layer, a lower electrode on the base layer, a sacrificial pattern on the lower electrode, and an insulation film on the base layer and covering the lower electrode and the sacrificial pattern;
providing a light-emitting opening in the insulation film;
providing a conductive partition wall layer on the insulation film, the conductive partition wall layer comprising the light-emitting opening;
providing in the conductive partition wall layer, an upper opening corresponding to the light-emitting opening; and
providing a lower opening in the sacrificial pattern,
wherein the method is a method of manufacturing a display device.

16. The method of claim 15, further comprising:
providing a light-emitting pattern on the lower electrode, and inside the upper opening, the light-emitting opening, and the lower opening; and
providing an upper electrode on the light-emitting pattern, the upper electrode being on an inner surface of a first conductive layer having the upper opening.

17. The method of claim 15, wherein an atomic percent of indium in the sacrificial pattern is less than about 0.1 at %.

18. The method of claim 15, wherein the conductive partition wall layer comprises a first conductive layer and a second conductive layer on the first conductive layer, and
wherein the providing of the upper opening comprises:
providing a preliminary upper opening in the conductive partition wall layer by dry-etching the first conductive layer and the second conductive layer; and
providing the upper opening from the preliminary upper opening by wet-etching the first conductive layer and the second conductive layer to provide a conductive partition wall from the conductive partition wall layer, and
a chlorine-containing etching gas is used during the dry-etching.

19. The method of claim 15, wherein the providing of the lower opening in the sacrificial pattern is performed by using wet etching, and
an etch rate of the lower electrode is less than an etch rate of the sacrificial pattern.

20. The method of claim 15, wherein the sacrificial pattern is doped with aluminum, and comprises at least one selected from among gallium oxide, zinc oxide, and tin oxide.
